(19) United States
(12) Patent Application Publication
(10) Pub. No.: US 2007/0215916 A1
(43) Pub. Date: Sep. 20, 2007

(54) SEMICONDUCTOR DEVICE AND MANUFACTURING METHOD THEREOF

(75) Inventors: Yoshihiro MINAMI, Fujisawa-Shi (JP); Tomoaki SHINO, Kawasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/609,013

(22) Filed: Dec. 11, 2006

(30) Foreign Application Priority Data
Mar. 3, 2006 (JP) 2006-058058

(51) Int. Cl. H01L 21/8234; H01L 29/76

(52) U.S. Cl. 257/288; 438/197

(57) ABSTRACT

This disclosure concerns a method of manufacturing a semiconductor device including preparing a support substrate including a surface region consisting of a semiconductor single crystal; forming a porous semiconductor layer by transforming the surface region of the support substrate into a porous layer; epitaxially growing a single-crystal semiconductor layer on the porous semiconductor layer; forming an opening reaching the porous semiconductor layer by removing a part of the single-crystal semiconductor layer; forming a cavity between the single-crystal semiconductor layer and the support substrate by removing the porous semiconductor layer through the opening; and filling the cavity with an insulating film or a conductive film.

### CROSS-REFERENCE TO RELATED APPLICATION

This application is based upon and claims the benefit of priority from the prior Japanese Patent Applications No. 2006-58058, filed on Mar. 3, 2006, the entire contents of which are incorporated herein by reference.

### BACKGROUND OF THE INVENTION

1. Field of the Invention

The present invention relates to a semiconductor device and a manufacturing method thereof. For example, the invention relates to a semiconductor memory device of a memory-logic hybrid-integrated type formed on a bulk substrate having an SOI structure, and to a manufacturing method of the semiconductor memory device.

2. Related Art

Recently, floating-body-cell (FBC) memory devices are expected as a semiconductor memory that replaces DRAMs. The FBC memory device is configured as follows. A MOSFET including a floating body (hereinafter, also “body region”) is formed on an SOI substrate. Each FBC stores therein data “1” or “0” according to the number of majority carrier accumulated in the body region of the FBC. The FBC memory device is, therefore, formed on the SOI substrate.

However, in a case of a memory-logic hybrid-integrated semiconductor memory device, it is preferable to form logic elements not on the SOI substrate but on a bulk substrate. This is because existing design resources (design library) that have been piled up by development so far can be made effective use of if the logic element is formed on the bulk substrate. To provide the logic region on the bulk substrate, partial removal of an SOI layer and a buried oxide (BOX) layer on the SOI substrate is considered. If so, a difference in height or level occurs between the memory region and the logic region, with the result that focus offset in a lithography process and planarization defect in a CMP process occur.

Moreover, because of higher in cost than the bulk substrate, a cost of the memory-logic hybrid-integrated semiconductor memory device is disadvantageously increased.

### SUMMARY OF THE INVENTION

A method of manufacturing a semiconductor device according to an embodiment of the present invention comprises preparing a support substrate including a surface region consisting of a semiconductor single crystal; forming a porous semiconductor layer by transforming the surface region of the support substrate into a porous layer; epitaxially growing a single-crystal semiconductor layer on the porous semiconductor layer; forming an opening reaching the porous semiconductor layer by removing a part of the single-crystal semiconductor layer; forming a cavity between the single-crystal semiconductor layer and the support substrate by removing the porous semiconductor layer through the opening; and filling the cavity with an insulating film or a conductive film.

A method of manufacturing a semiconductor device according to an embodiment of the present invention comprises preparing a support substrate; forming an insulation layer on a source formation region of the support substrate; epitaxially growing a first single-crystal semiconductor layer on the support substrate by using the insulation layer as a mask; forming a porous semiconductor layer by transforming the first single-crystal semiconductor layer into a porous layer; epitaxially growing a second single-crystal semiconductor layer on the porous semiconductor layer and on the insulation layer; forming an opening reaching the porous semiconductor layer by removing a part of the second single-crystal semiconductor layer; forming a cavity between the second single-crystal semiconductor layer and the support substrate by removing the porous semiconductor layer through the opening; and filling the cavity with an insulating film.

A semiconductor device according to an embodiment of the present invention comprises a support substrate; an insulating film provided on the support substrate; a semiconductor layer provided on the insulating film; a source layer and a drain layer formed in the semiconductor layer; a body region provided in the semiconductor layer between the source layer and the drain layer, the body region being in an electrically floating state and accumulating or discharging charges for storing data; and a protrusion formed on a surface of the support substrate and consisting of a semiconductor material so that the insulating film below the body region is thinner than the insulating film below the drain layer.

### BRIEF DESCRIPTION OF THE DRAWINGS

FIGS. 1A to 10 are plan views or cross-sectional views showing a manufacturing method of an FBC memory device according to a first embodiment of the present invention;

FIG. 11 is a cross-sectional view of the logic circuit element;

FIG. 12 is a plan view of an FBC memory device according to a second embodiment of the present invention;

FIG. 13 is a cross-sectional view taken along a line 13-13 of FIG. 12;

FIG. 14 is a cross-sectional view taken along a line 14-14 of FIG. 12;

FIG. 15 is a cross-sectional view taken along a line 15-15 of FIG. 12;

FIGS. 16A to 22B are plan views or cross-sectional views showing a manufacturing method of the FBC memory device according to the second embodiment;

FIGS. 23A to 32 are plan views or cross-sectional views showing a manufacturing method of an FBC memory device according to a third embodiment of the present invention;

FIG. 33 is a cross-sectional view of an FBC memory device according to a fourth embodiment of the present invention;

FIGS. 34A to 42B are plan views or cross-sectional views showing a manufacturing method of the FBC memory device according to the fourth embodiment;

FIGS. 43A to 49 are plan views or cross-sectional views showing a manufacturing method of an FBC memory device according to a fifth embodiment of the present invention;

FIG. 50 is a cross-sectional view showing an FBC memory device according to a fifth embodiment;

FIG. 51 is a cross-sectional view of an FBC memory device according to a sixth embodiment of the present invention;

FIGS. 52A to 59 are plan views or cross-sectional views showing a manufacturing method of the FBC memory device according to the sixth embodiment;

FIGS. 60A to 66 are plan views or cross-sectional views showing a manufacturing method of an FBC memory device according to a seventh embodiment of the present invention;

FIG. 67 is a cross-sectional view of an FBC memory device according to an eighth embodiment of the present invention; and

FIG. 68 is a cross-sectional view of an FBC memory device according to a ninth embodiment of the present invention.

### DETAILED DESCRIPTION OF THE INVENTION

Hereafter, embodiments of the present invention will be described with reference to the drawings. Note that the invention is not limited to the embodiments. In the following embodiments, it is assumed that memory cells are all n-type FETs (n-FETs). However, the n-FETs can be replaced by p-type FETs (p-FETs).

### First Embodiment

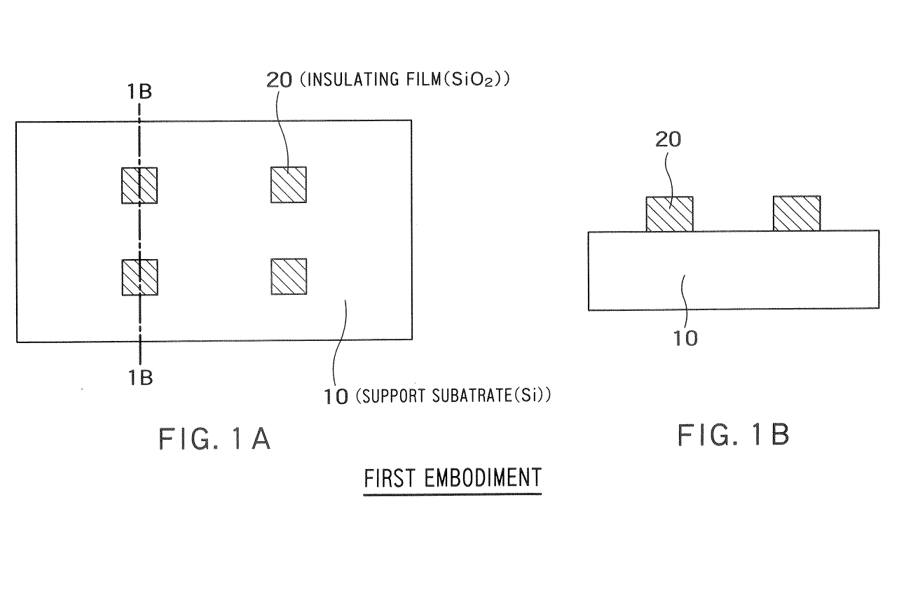

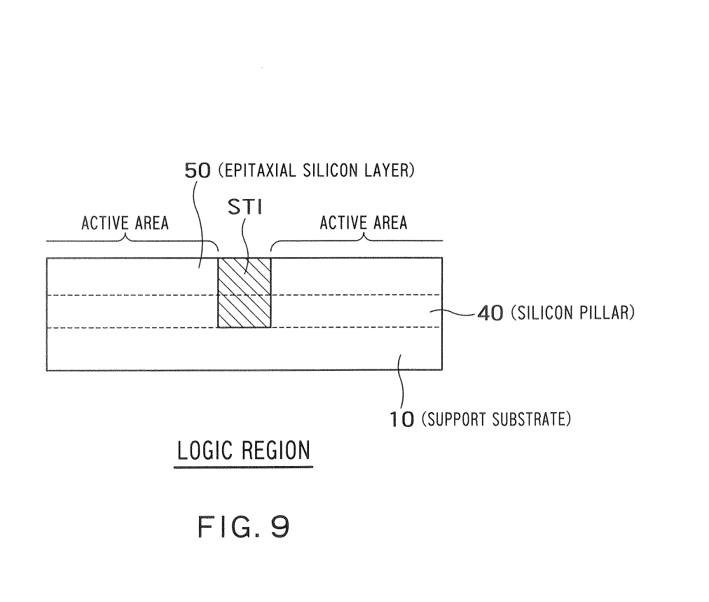

FIGS. 1A to 10 are plan views or cross-sectional views showing a manufacturing method of an FBC memory device according to a first embodiment of the present invention. FIGS. 1A to 10 except for FIG. 9 show a memory region. FIG. 9 shows a logic region. FIGS. 1A, 2A, 3A 4A, 5A, and 7 are plan views, and FIGS. 1B, 2B, 3B, 4B, 5B, 5C, 6A, 6B, 8A, 8B, 9, and 10 are cross-sectional views.

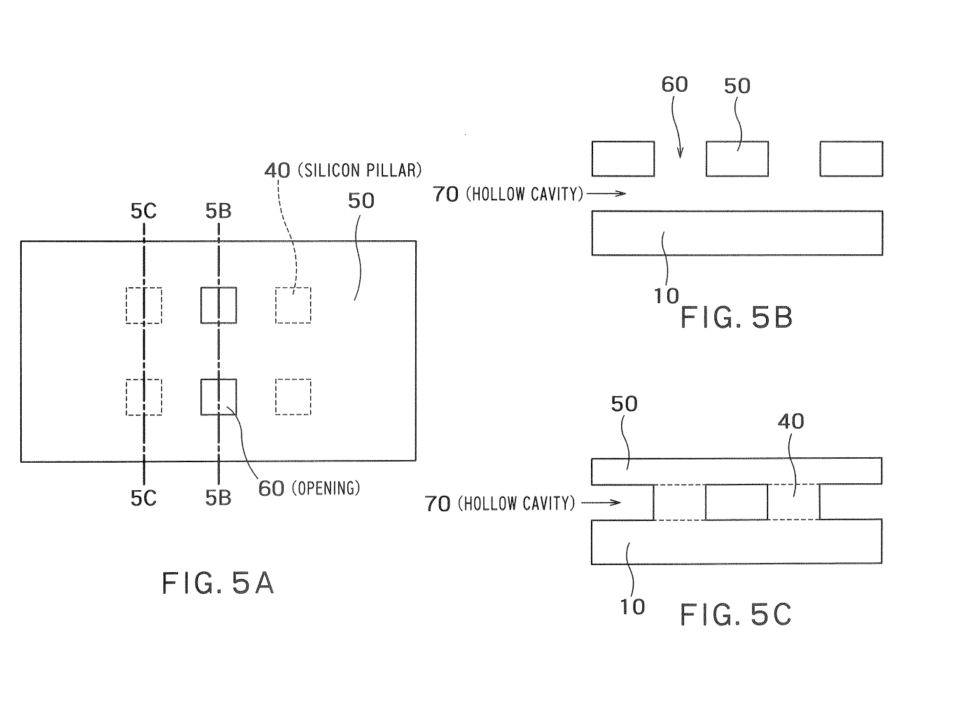

First, a support substrate 10 consisting of silicon single crystal is prepared. As the support substrate 10, not an SOI substrate but an ordinarily used bulk silicon substrate can be used. As shown in FIGS. 1A and 1B, an insulating film 20 used as a mask material is deposited on the support substrate 10, and etched into a predetermined pattern by reactive ion etching (RIE). FIG. 1B is a cross-sectional view taken along a line 1B-1B of FIG. 1A. The insulating film 20 can be, for example, a silicon oxide, a silicon nitride film, or a photoresist. Silicon pillars 40 are provided each at a position of the insulating film 20 to prevent falling of a single-crystal semiconductor layer (see FIG. 5C). It is, therefore, preferable that the pattern of the insulting film 20 is substantially uniformly distributed in the memory region. Furthermore, because the silicon pillar 40 is removed in a subsequent shallow-trench-isolation (STI) forming process, a plan pattern of the insulating film 20 is preferably included in a plan pattern of an STI region.

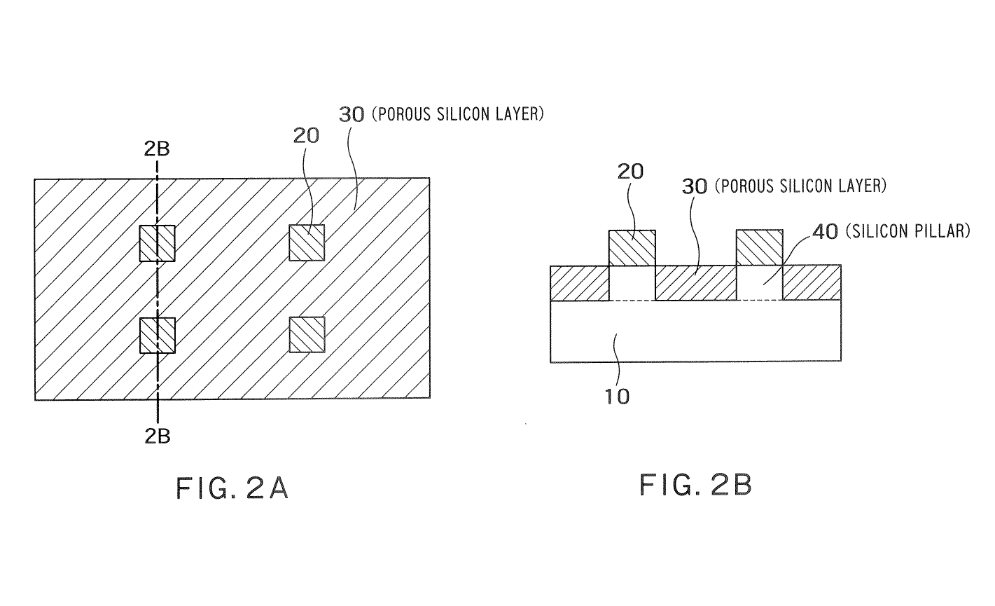

Using the insulating film 20 as a mask, a surface region of the support substrate 10 is anodized. As shown in FIGS. 2A and 2B, the surface region of the support substrate 10 is transformed into a porous silicon layer 30. FIG. 2B is a cross-sectional view taken along a line 2B-2B of FIG. 2A. At the time of transforming the surface region of the support substrate 10 into the porous silicon layer 30, the support substrate 10 under the insulating film 20 is not transformed into the porous silicon layer 30. The anodization is a treatment of carrying a current to the support substrate 10 in a solution that contains hydrofluoric acid (HF) and ethanol. By performing the anodization, pores at a diameter of several nanometers are formed in the surface region of the support substrate 10, and the pores extend into the support substrate 10 during the anodization. As a result, many pores extending in perpendicular direction are formed in a surface of the support substrate 10, thus transforming the surface region into the porous silicon layer 30. At this moment, because no anodization current is applied to a region of the support substrate 10 covered with the insulating film 20, the silicon pillar 40 remains in the region. On the other hand, a region of the support substrate 10 that is not covered with the insulating film 20 is selectively transformed into the porous silicon layer 30.

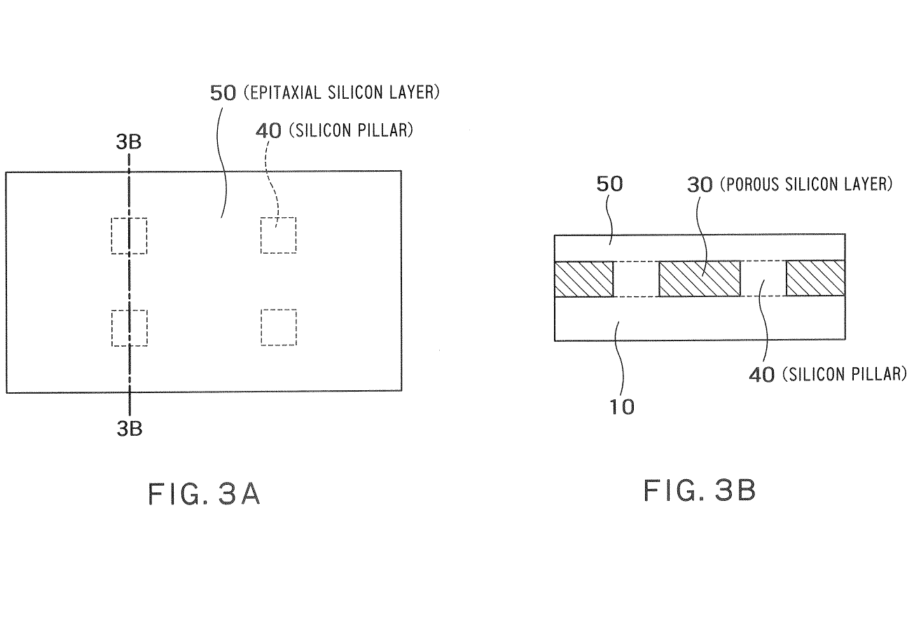

After removing the insulating film 20, an epitaxial silicon layer (hereinafter, also “epitaxial layer”) 50 is formed on the porous silicon layer 30 and the silicon pillar 40 by epitaxial growth as shown in FIGS. 3A and 3B. FIG. 3B is a cross-sectional view taken along a line 3B-3B of FIG. 3A. The porous silicon layer 30 consists of the single-crystal silicon, therefore the epitaxial silicon layer 50 can be formed by simply epitaxially growing a single-crystal silicon layer.

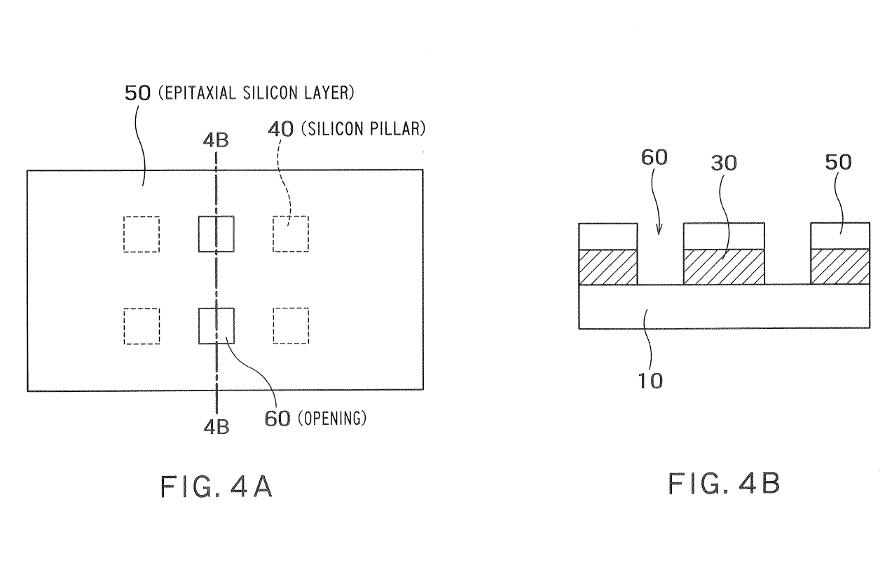

Next, as shown in FIGS. 4A and 4B, a part of the epitaxial layer 50 is etched and openings 60 that reach the porous silicon layer 30 are formed by using lithography and the RIE. FIG. 4B is a cross-sectional view taken along a line 4B-4B of FIG. 4A. The openings 60 are employed to remove the porous silicon layer 30. Therefore, it is preferable that the openings 60 are distributed substantially uniformly in the memory region similarly to the silicon pillars 40. Moreover, the openings 60 are removed in the subsequent STI forming process similarly to the silicon pillars 40. Therefore, a plan pattern of the openings 60 is included in that of the STI region. Each opening 60 can be provided, for example, between adjacent silicon pillars 40.

The porous silicon layer 30 is isotropically etched through the openings 60 using a hydrofluoric-acid-based solution (e.g., HF+H₂O₂ solution). The porous silicon layer 30 is selectively etched relative to the nonporous support substrate 10 and the nonporous epitaxial layer 50. As a result, as shown in FIGS. 5A, 5B, and 5C, a hollow cavity 70 is formed between the epitaxial layer 50 and the support substrate 10. As shown in FIG. 5C, the epitaxial layer 50 is supported by the silicon pillars 40 on the support substrate 10. Therefore, the epitaxial layer 50 does not fall into the support substrate 10.

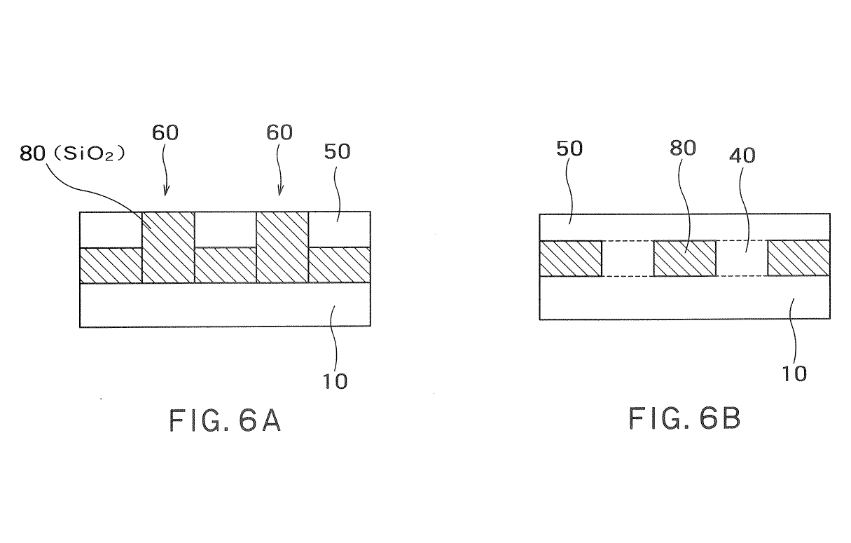

As shown in FIGS. 6A and 6B, an insulating film 80 is filled up into the cavity 70 by low pressure chemical vapor deposition (LPCVD) or the like. FIG. 6A is a cross-sectional view subsequent to FIG. 5B for showing the manufacturing method, and FIG. 6B is a cross-sectional view subsequent to FIG. 5C for showing the manufacturing method. The insulating film 80 is, for example, a silicon oxide film. Before filling the cavity 70 with the insulating film 80, a thin thermal oxide film can be formed in an inner wall of the cavity 70. In the process of filling the cavity 70 with the insulating film 80, the surface region of the support substrate 10 is formed into an SOI structure except for the silicon pillars 40 and the openings 60.

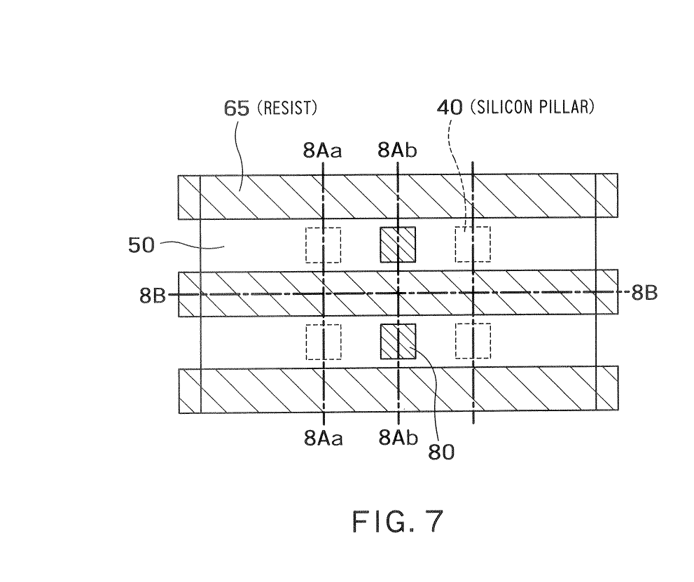

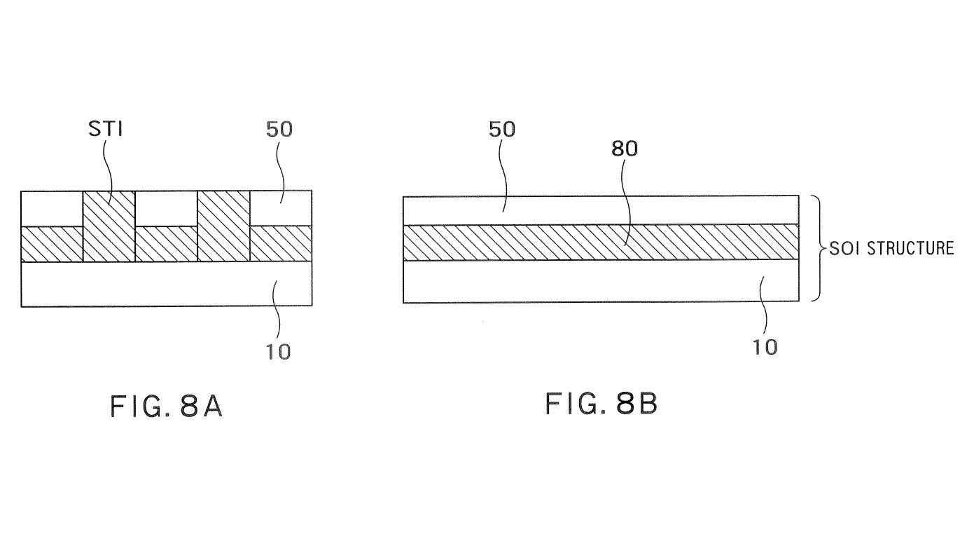

To form the STI region, an active area of the epitaxial layer 50 is covered with a resist 65 as shown in FIG. 7. The epitaxial layer 50, the silicon pillars 40, and the insulating film 80 in the openings 60 in an element isolation region are removed, thereby forming trenches. By filling each trench with a silicon oxide film, the STI region is formed as shown in FIG. 8A. FIG. 8A corresponds to a cross section along lines 8Aa-8Aa and 8Ab-8Ab of FIG. 7 after formation of the STI regions. FIG. 8B corresponds to a cross section along a line 8B-8B of FIG. 7 after the formation of the STI regions. The epitaxial layer 50 other than the STI regions serves as the active area. It is to be noted that the active area has the SOI structure.

In a logic formation region, the silicon pillars 40 are provided uniformly in the entire active area. This enables the active area in the logic formation region to remain as the bulk substrate without having the SOI structure. More specifically, the entire active area in the logic formation region is covered with the insulating film 20 serving as the protection film as shown in FIG. 1A, and protected from the anodization. By doing so, in the logic formation region, only the isolation region is transformed into the porous region by the anodization while the silicon pillars 40 remain in the active area. As a result, as shown in FIG. 9, in the logic formation region, the active area consists in a bulk substrate state. In the active area in the logic formation region, the silicon pillars 40 and the epitaxial layer 50 are formed. Therefore, the active area in the logic formation region is equal in height or level to that in the memory region. Namely, no difference in height or level is generated between the logic formation region and the memory region.

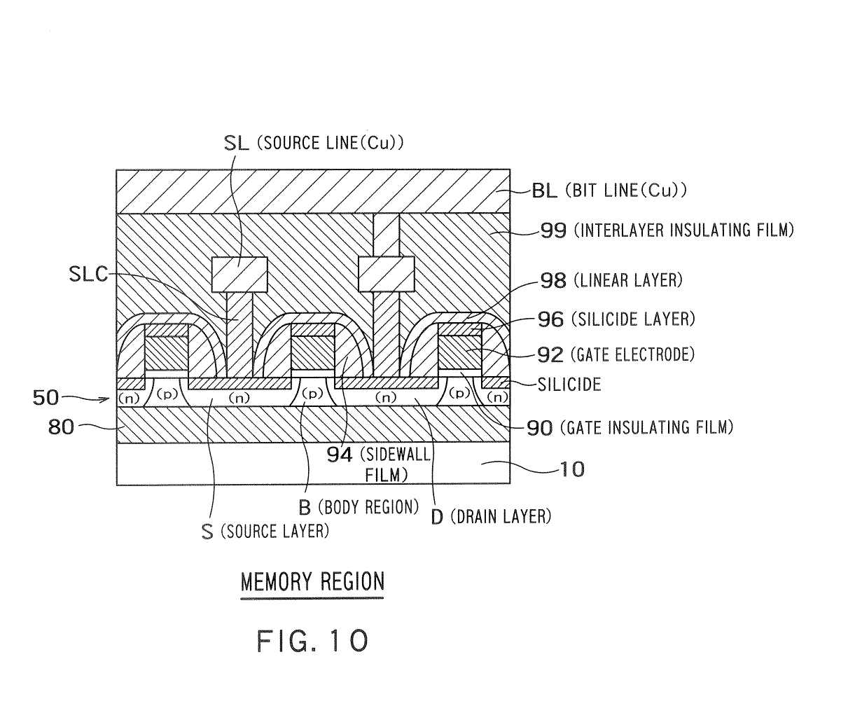

Thereafter, an FBC memory cell and a logic circuit element are formed by a known manufacturing method. FIG. 10 is a cross-sectional view of an example of the FBC memory cell. The FBC memory cell according to the first embodiment includes the support substrate 10, a silicon oxide film (BOX) 80 provided on the support substrate 10, a semiconductor layer (an SOI layer) 50 provided on the silicon oxide film 80, a p-type source layer S and a drain layer D provided in the semiconductor layer 50, a body region B provided in the semiconductor layer 50 between the source layer S and the drain layer D, a gate insulating film 90 provided on the body region B, a gate electrode 92 provided on the gate insulating film 90, a silicide layer 96 provided on the source layer S, the drain layer D, and the gate electrode 92, a sidewall film 94 provided on a sidewall of the gate electrode 92, a liner layer 98 covering up the silicide layer 96 and the sidewall film 94, an interlayer insulating film 99 deposited on the linear layer 98, a source line SL electrically connected to the source layer S through a source-line contact SLC, and a bit line BL electrically connected to the drain layer D through a bit-line contact BLC.

The body region B is, for example, an n-type semiconductor layer. The body region B, which is in an electrically floating state, can store data therein by accumulating or discharging charges. If the FBC memory cell is, for example, an n-type FET, the FBC memory cell stores therein data “1” or “0” according to the number of holes accumulated in the body region B.

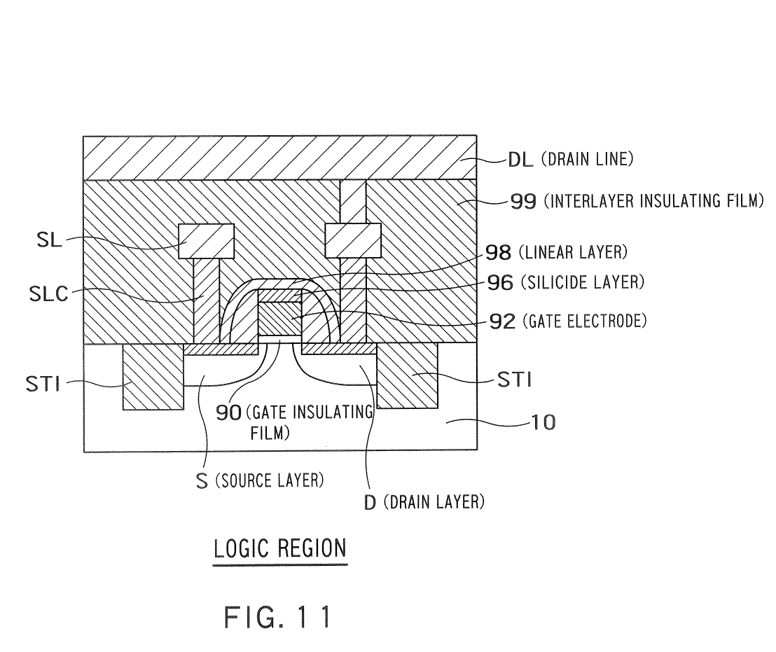

FIG. 11 is a cross-sectional view of the logic circuit element. The logic circuit element is formed on the active area shown in FIG. 9. Therefore, the logic circuit element shown in FIG. 11 can be formed at the same height as that of the FBC memory cell shown in FIG. 10.

In the manufacturing method according to the first embodiment, the insulating film 80 in the memory region is filled at a location where the porous silicon film 30 is present. In addition, a thickness of the silicon pillar 40 is determined by formation of the porous silicon film 30. Accordingly and naturally, the silicon pillar 40 is equal in thickness to the porous silicon film 30. A surface level of the epitaxial layer 50 in the memory region is substantially equal to that of the epitaxial layer 50 in the logic formation region. That is, height levels of the active areas in the memory region and the logic formation region are substantially equal to each other, so that no difference in height or level is generated on a boundary between the memory region and the logic formation region. Accordingly, focus offset in a lithography process and planarization defect in a CMP process do not occur between the memory region and the logic region.

In the manufacturing method according to the first embodiment, the SOI structure is formed in the memory region using not the SOI substrate but the bulk silicon substrate. Therefore, the FBC memory device according to the first embodiment is lower in cost than that manufactured using the SOI substrate.

Furthermore, according to a technique disclosed in JP-A No. H02-271551 (KOKAI), an amorphous layer is formed in a silicon substrate by implanting ions into the silicon substrate. Thereafter, by filling a cavity formed by removing the amorphous layer with a silicon oxide film, an SOI structure is formed. If the SOI structure is formed by the method disclosed in JP-A No. H02-271551 (KOKAI), however, an SOI layer on a BOX layer is susceptible to damage by the ion implantation. To undo the damage, it is necessary to perform a heat treatment on the silicon substrate.

In the first embodiment, by contrast, no ions are implanted into the SOI layer for the formation of the SOI structure. Thanks to this, the SOI layer is less susceptible to damage, and there is no need to perform any heat treatment to undo the damage.

### Second Embodiment

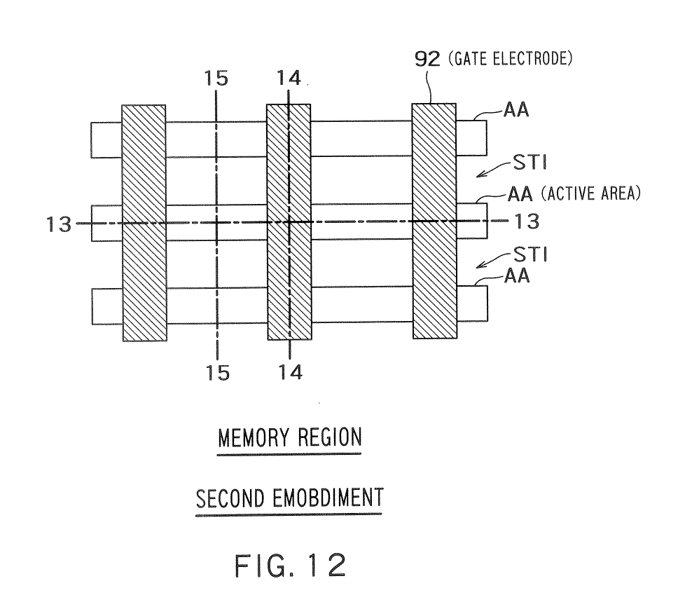

FIG. 12 is a plan view of an FBC memory device according to a second embodiment of the present invention. Since a logic circuit element according to the second embodiment is the same as the logic circuit element according to the first embodiment, the logic circuit element according to the second embodiment will not be shown and explained herein.

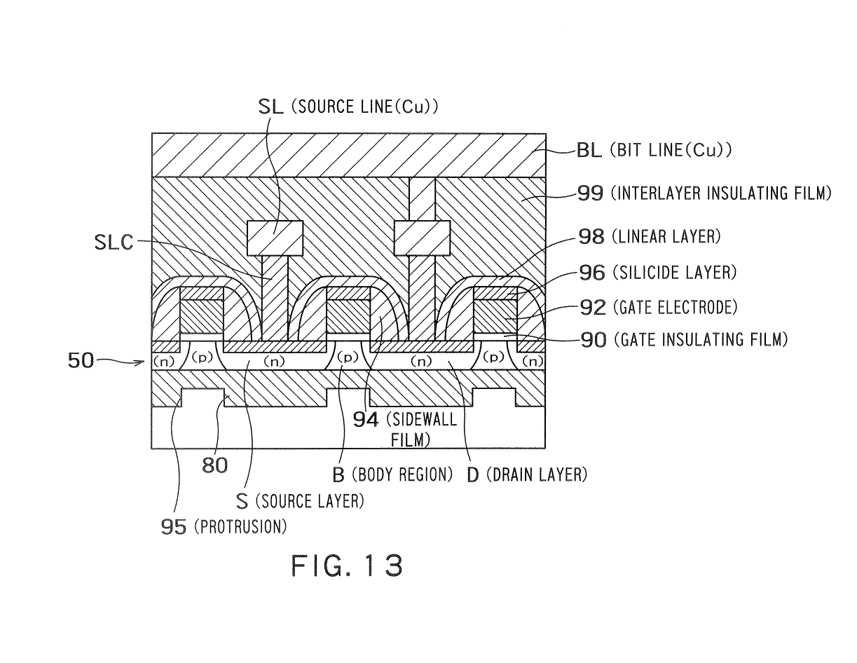

FIG. 13 is a cross-sectional view taken along a line 13-13 of FIG. 12. The second embodiment differs from the first embodiment in that protrusions 95 are formed on a surface of the support substrate 10. Other configurations according to the second embodiment can be the same as those according to the first embodiment.

Each protrusion 95 consists of the same semiconductor material (e.g. silicon single crystal) as that of the support substrate 10, and is provided under the body region B. Accordingly the insulating film 80 below the body region B is thinner than the insulating film 80 below the source layer S and the drain layer D.

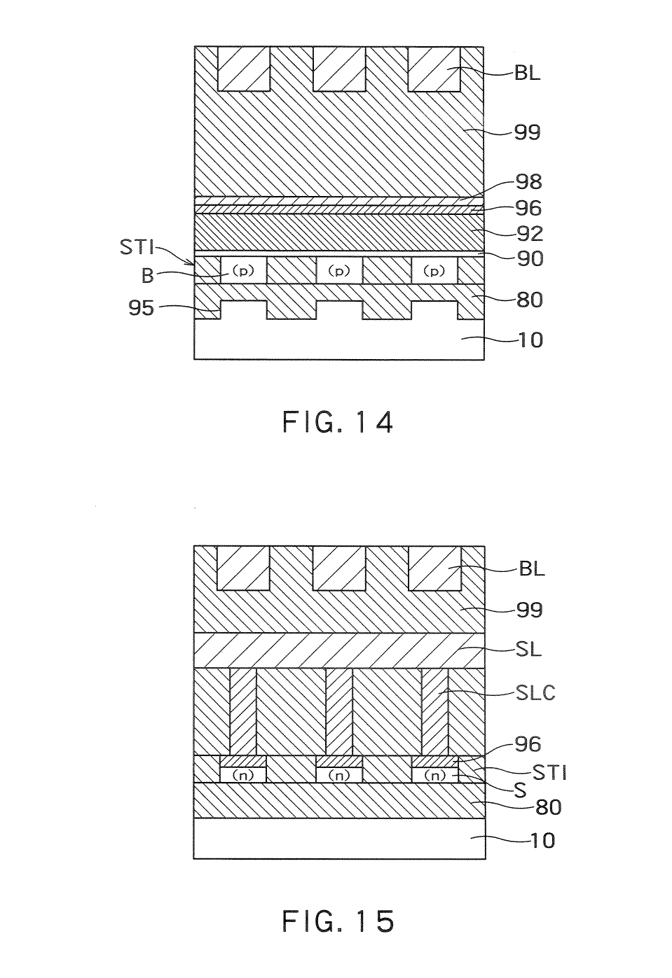

FIG. 14 is a cross-sectional view taken along a line 14-14 of FIG. 12. FIG. 15 is a cross-sectional view taken along a line 15-15 of FIG. 12. As shown in FIGS. 14 and 15, the protrusions 95 are formed below the body region B but not below the source layer S.

By providing the protrusions 95, a capacity between the body region B and the support substrate 10 can be increased without increasing a capacity between the source layer S and the support substrate 10 and that between the drain layer D and the source substrate 10. By suppressing parasitic capacities of the source layer S and the drain layer D, it is possible to suppress reduction in an operating speed of the FBC memory cell. Moreover, by increasing the capacity between the body region B and the support substrate 10, a signal difference (threshold voltage difference) between the data “0” and the data “1” can be increased.

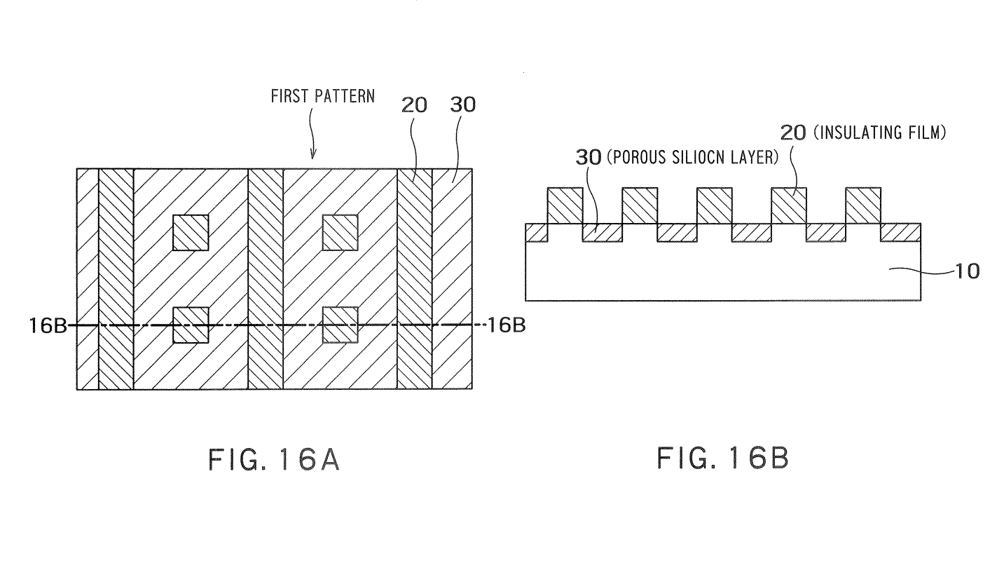

FIGS. 16A to 22B are plan views or cross-sectional views showing a manufacturing method of the FBC memory device according to the second embodiment. FIGS. 16A, 17A, 18A 19A, 20A, 21A, and 22A are plan views, and FIGS. 16B, 17B, 18B, 19B, 20B, 21B, and 22B are cross-sectional views.

First, similarly to the first embodiment, the support substrate 10 is prepared and the insulating film 20 serving as the mask material is formed on the support substrate 10. At the time of formation, the insulating film 20 covers up not only regions for forming the silicon pillars 40 but also those for forming the protrusions 95. The silicon pillars 40 are provided to prevent the single-crystal semiconductor layer from falling. It is, therefore, preferable that the pattern of the insulating film 20 in the regions for forming the silicon pillars 40 is substantially uniformly distributed in the memory region. Furthermore, because the silicon pillars 40 are removed in the subsequent STI forming process, the plan pattern of the insulating film 20 in the regions for forming the silicon pillars 40 is included in the plan pattern of the STI region. Because the protrusions 95 are formed below the body region B, the insulating film 20 in the regions for forming protrusions 95 is provided into a line shape (stripe shape) along the adjacent body region B.

Next, the surface region of the support substrate 10 is anodized using the insulating film 20 as a mask (first porous layer formation). As a result, as shown in FIGS. 16A and 16B, the surface region of the support substrate 10 that is not covered with the insulating film 20 is transformed into the porous silicon layer 30. FIG. 16B is a cross-sectional view taken along a line 16B-16B of FIG. 16A. It is assumed that a plan pattern of the porous silicon layer 30 formed at the first porous layer formation is a first pattern. At the time of the first porous layer formation, the support substrate 10 under the insulating film 20 is not transformed into the porous silicon layer.

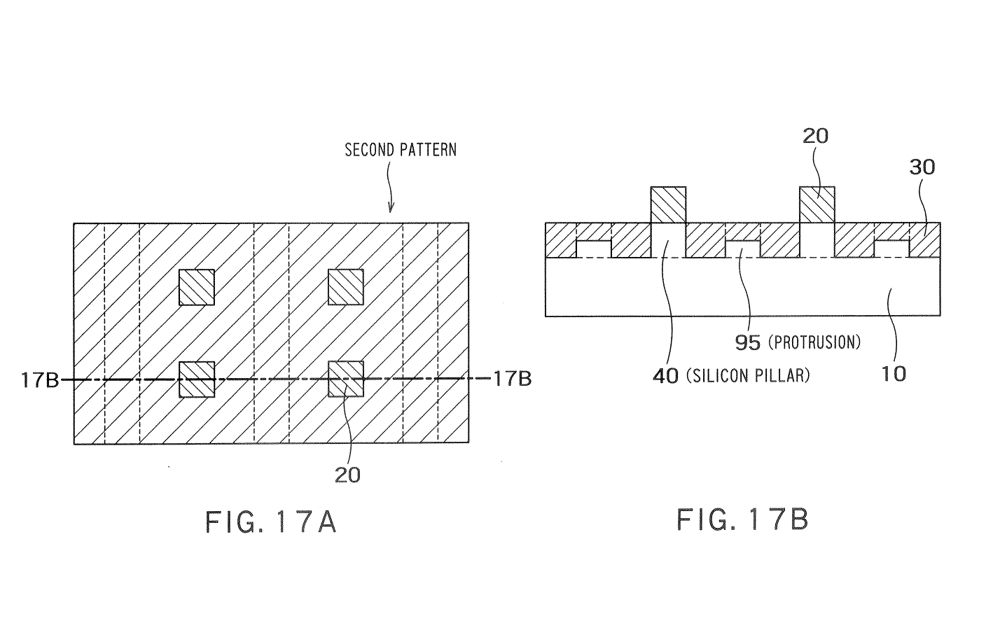

Using the lithography and the etching, the insulating film 20 above the regions for forming the protrusions 95 is removed while leaving the insulating film 20 on the regions for forming the silicon pillars 40. Using the insulating film 20 as a mask, the surface region of the support substrate 10 is anodized (second porous layer formation). As a result, as shown in FIGS. 17A and 17B, the porous state of the surface region of the support substrate 10 that is not covered with the insulating film 20 is further accelerated. FIG. 17B is a cross-sectional view taken along a line 17B-17B of FIG. 17A. It is assumed that the plan pattern of the porous silicon layer 30 formed at the second porous layer formation is a second pattern. In a region in which the first pattern overlaps with the second pattern, the surface region of the support substrate 10 is subjected to the first porous layer formation and the second porous layer formation, so that the porous silicon layer 30 becomes thicker. On the other hand, in a region included in one of the first or second pattern, the surface region of the support substrate 10 is subjected to one of the first porous layer formation and the second porous layer formation, so that the porous silicon layer 30 is relatively thin. In the second embodiment, the second pattern is the plan pattern including the first pattern and the pattern of the protrusions 95. Therefore, the surface region of the support substrate 10 in the first pattern (the active area in the memory region) is subjected to both the first porous layer formation and the second porous layer formation. Therefore, the porous silicon layer 30 in the first pattern is relatively thick. The surface region of the support substrate 10 in the pattern of the protrusions 95 is subjected only to the second porous layer formation. Therefore, the porous silicon layer 30 in the pattern of the protrusions 95 is relatively thin. Moreover, because the regions for forming the silicon pillars 40 are covered with the insulating film 20, the surface region of the support substrate 10 in the pattern of the silicon pillars 40 is not transformed into the porous silicon layer 30.

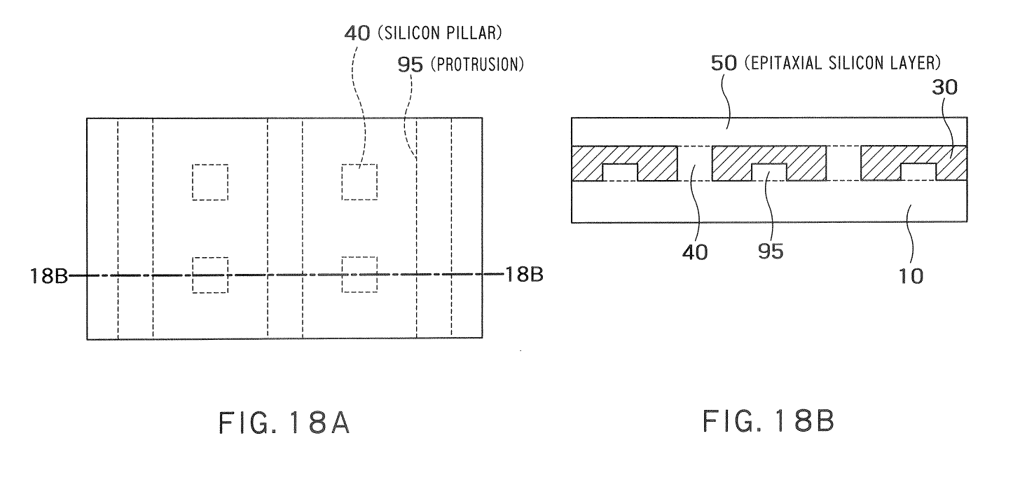

After removing the insulating film 20, the epitaxial layer 50 is formed on the porous silicon layer 30 and the silicon pillars 40 by the epitaxial growth as shown in FIGS. 18A and 18B. FIG. 18B is a cross-sectional view taken along a line 18B-18B of FIG. 18A.

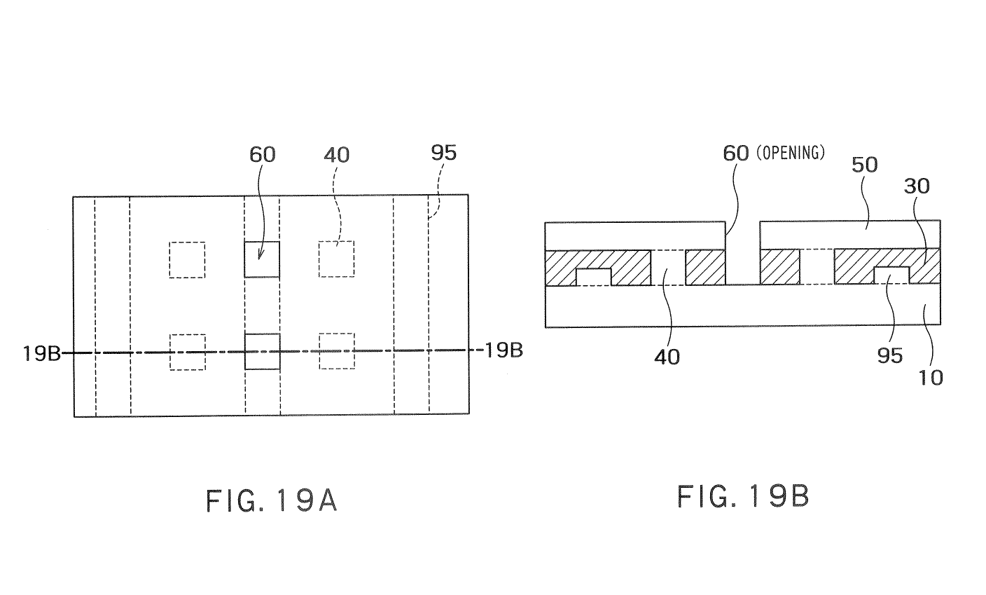

Using the lithography and the RIE, a part of the epitaxial layer 50 is etched and the openings 60 that reach the porous silicon layer 30 are formed as shown in FIGS. 19A and 19B. FIG. 19B is a cross-sectional view taken along a line 19B-19B of FIG. 19A. Because the openings 60 are employed to remove the porous silicon layer 30, the openings 60 are preferably distributed substantially uniformly in the memory region similarly to the silicon pillars 40. Moreover, because the openings 60 are removed in the subsequent STI forming process similarly to the silicon pillars 40, the plan pattern of the openings 60 is included in the plan pattern of the STI region. Each opening 60 can be provided, for example, between the adjacent silicon pillars 40.

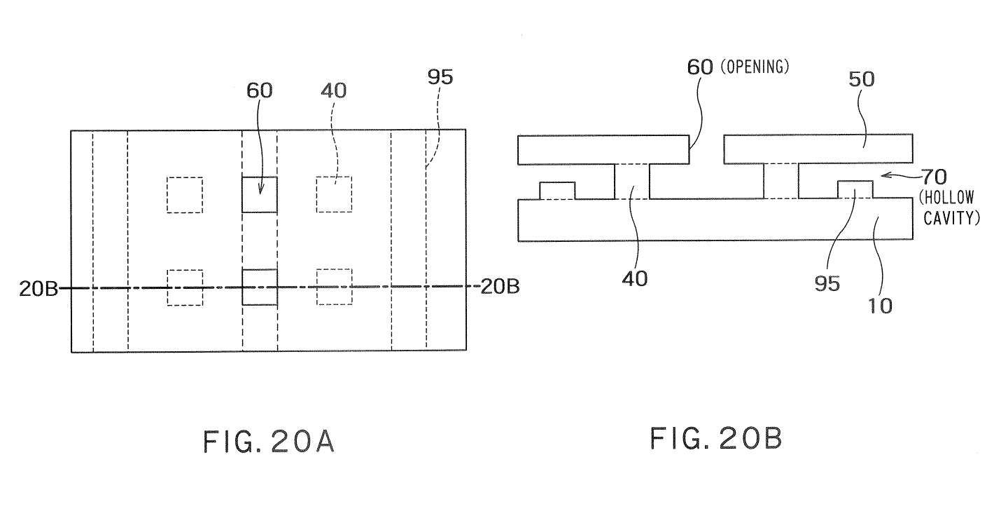

The porous silicon layer 30 is isotropically etched through the openings 60 using the hydrofluoric-acid-based solution (e.g., HF+H₂O₂ solution). As a result, as shown in FIGS. 20A and 20B, the hollow cavity 70 is formed between the epitaxial layer 50 and the support substrate 10, FIG. 20B is a cross-sectional view taken along a line 20B-20B of FIG. 20A. At the time of formation, the epitaxial layer 50 is supported by the silicon pillars 40 on the support substrate 10. Therefore, the epitaxial layer 50 does not fall into the support substrate 10.

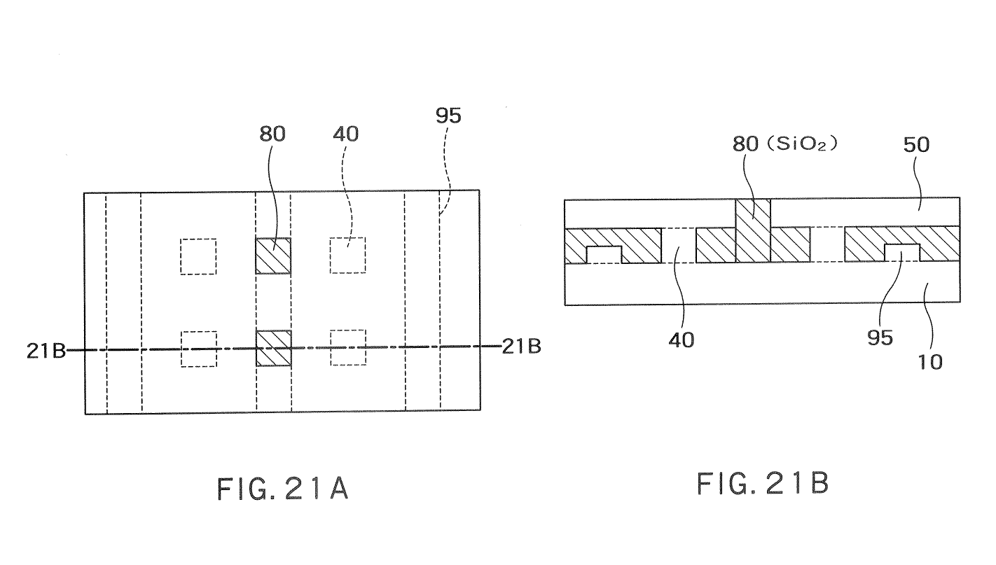

As shown in FIGS. 21A and 21B, the insulating film 80 is filled up into the cavity 70 by the LPCVD or the like through the openings 60. FIG. 21B is a cross-sectional view taken along a line 21B-21B of FIG. 21A. Before filling the cavity 70 with the insulating film 80, a thin thermal oxide film can be formed in an inner wall of the cavity 70. In the process of filling the cavity 70 with the insulating film 80, the surface region of the support substrate 10 is formed into an SOI structure except for the silicon pillars 40 and the openings 60.

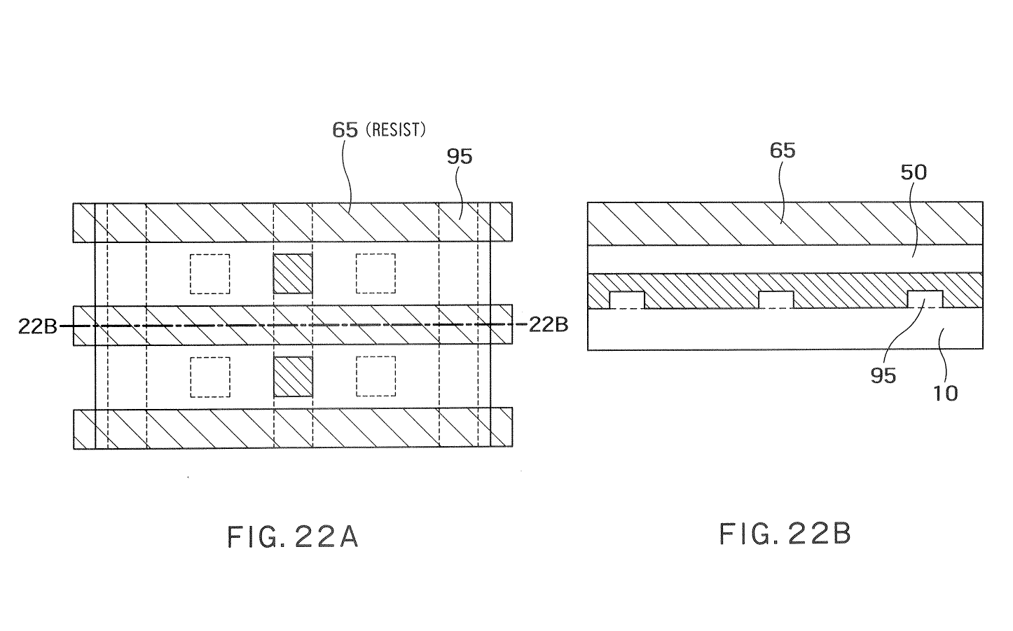

To form the STI region, the active area of the epitaxial layer 50 is covered with the resist 65 as shown in FIGS. 22A and 22B. FIG. 22B is a cross-sectional view taken along a line 22B-22B of FIG. 22A. The epitaxial layer 50, the silicon pillars 40, and the insulating film 80 in the openings 60 in the element isolation region are removed using the RIE or the like, thereby forming trenches. By filling each trench with the silicon oxide film, the STI region is formed as shown in FIGS. 14 and 15. The epitaxial layer 50 other than the STI regions serves as the active area. As shown in FIG. 13, the body region B is formed on the protrusions 95 shown in FIG. 22B.

In this manner, the FBC memory device according to the second embodiment can increase the signal difference between the data “0” and the data “1” by providing the protrusions 95. Furthermore, the second embodiment can exhibit the same advantages as those of the first embodiment.

### Third Embodiment

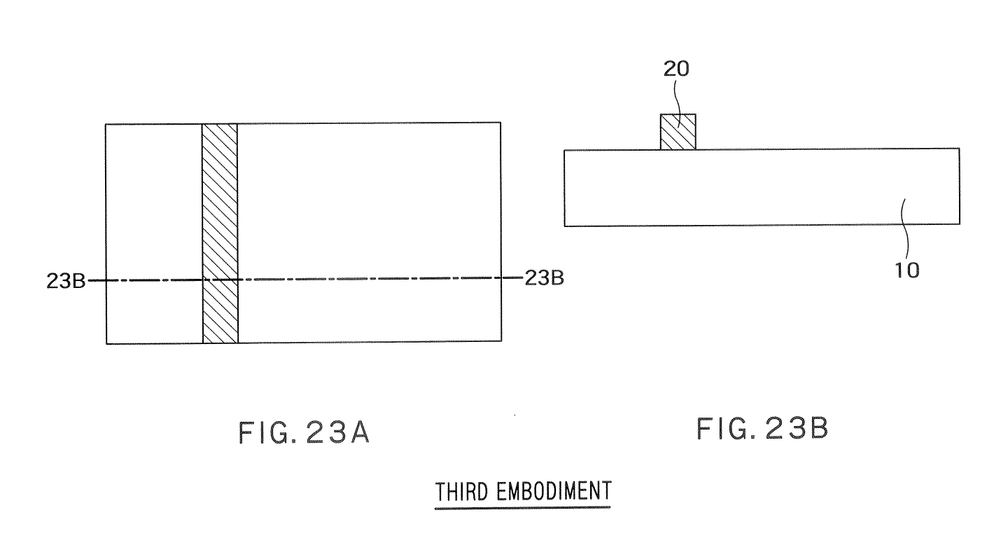

FIGS. 23A to 32 are plan views or cross-sectional views showing a manufacturing method of an FBC memory device according to a third embodiment of the present invention. FIGS. 23A, 24A, 25A, 26, and 30A are plan views, and FIGS. 23B, 24B, 25B, 27A to 29, 30B, 31A, 31B, and 32 are cross-sectional views. Since a logic circuit element according to the third embodiment is the same as the logic circuit element according to the first embodiment, the logic circuit element according to the third embodiment will not be shown and explained herein.

First, similarly to the first embodiment, the support substrate 10 is prepared and the insulating film 20 serving as the mask material is formed on the support substrate 10. At the time of formation, the insulating film 20 is formed into a line shape on the regions for forming the silicon pillars 40. In the third embodiment, the pattern of the silicon pillars 40 is the same as that of the source lines SL. Therefore, the insulating film 20 is formed in regions for forming the source line SL pattern.

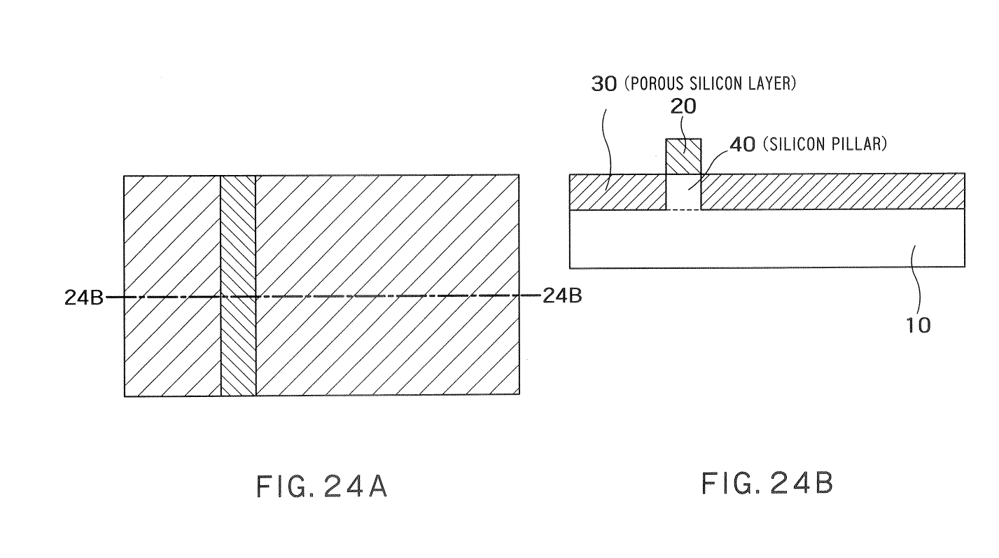

Next, the surface region of the support substrate 10 is anodized using the insulating film 20 as a mask. As a result, as shown in FIGS. 24A and 24B, the surface region of the support substrate 10 is transformed into the porous silicon layer 30. FIG. 24B is a cross-sectional view taken along a line 24B-24B in FIG. 24A. At the time of formation, the support substrate 10 below the insulating film 20 is not transformed by the silicon pillars 40 and remains as silicon single crystal.

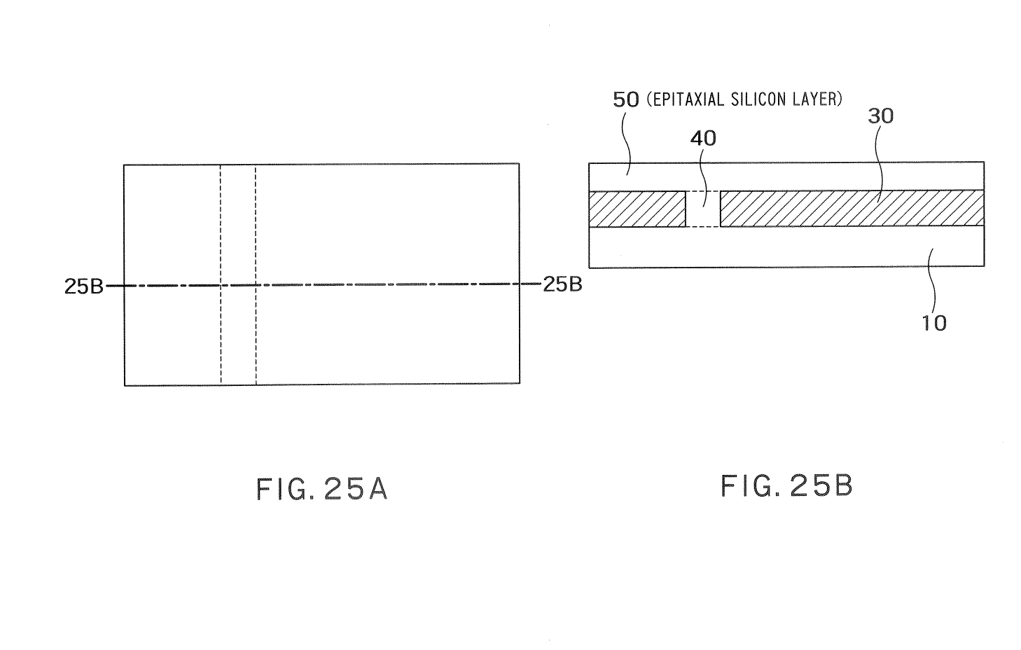

After removing the insulating film 20, the epitaxial layer 50 is formed on the porous silicon layer 30 and the silicon pillars 40 by the epitaxial growth as shown in FIGS. 25A and 25B. FIG. 25B is a cross-sectional view taken along a line 25B-25B of FIG. 25A.

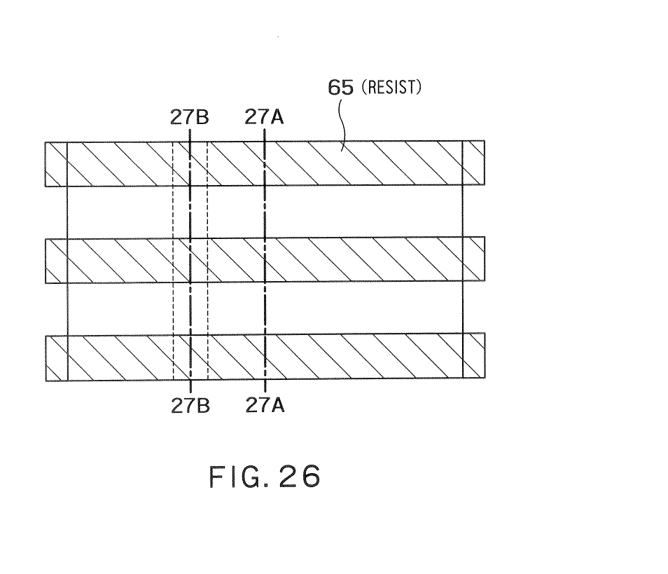

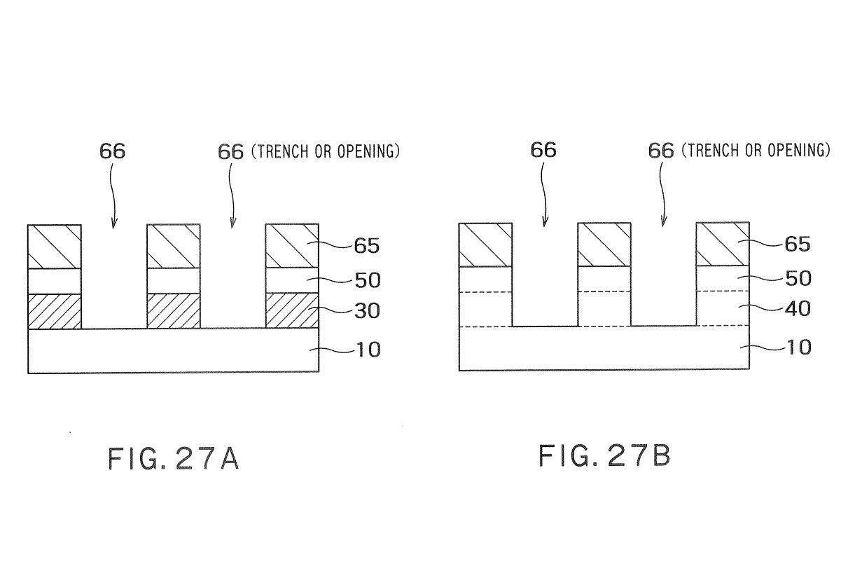

As shown in FIG. 26, the active area of the epitaxial layer 50 is covered with the resist 65. Using the RIE or the like, the epitaxial layer 50 and the silicon pillars 40 in the element isolation region are removed, thereby forming trenches or openings 66. FIG. 27A is a cross-sectional view taken along a line 27A-27A of FIG. 26 after formation of the trenches 66. FIG. 27B is a cross-sectional view taken along a line 27B-27B of FIG. 26 after formation of the trenches 66. The trenches or openings 66 are employed as openings to remove the porous silicon layer 30 and then as trenches to form the STI regions. In this manner, in the third embodiment, because the trenches or openings 66 function as both the openings and the trenches, there is no need to form a dedicated photomask to forming the openings. Furthermore, because the openings and the trenches can be formed in the same process, manufacturing process becomes shorter than those according to the first and second embodiments.

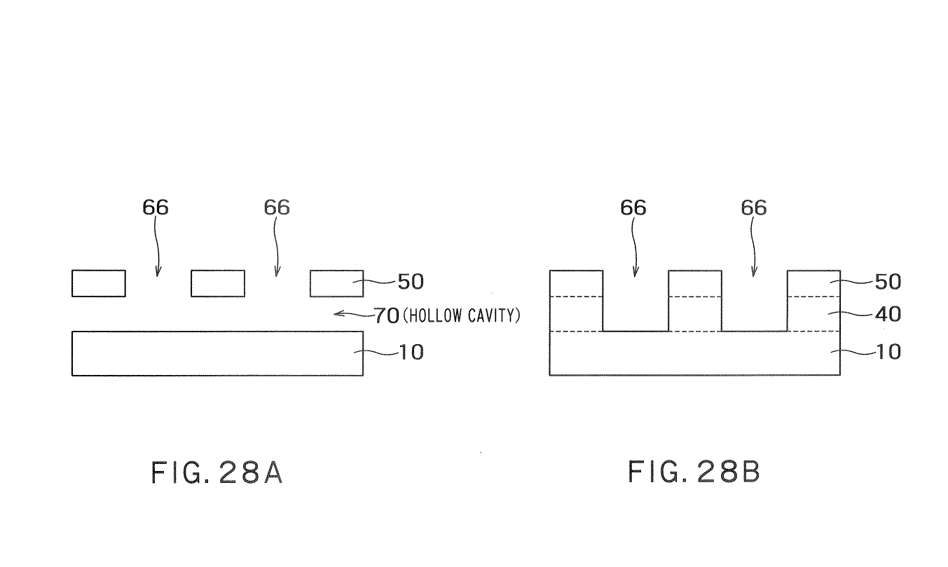

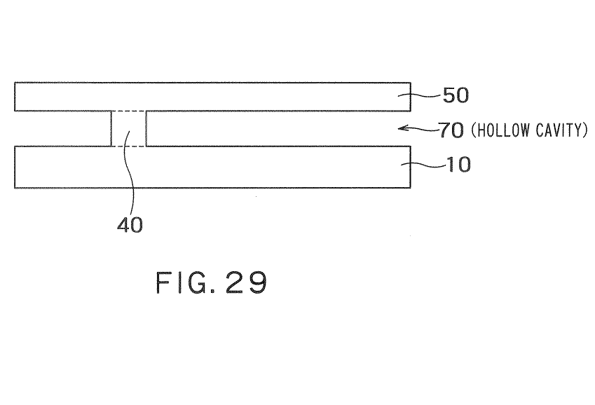

The porous silicon layer 30 is isotropically etched through the trenches or openings 66 using the hydrofluoric-acid-based solution (e.g., HF+H₂O₂ solution). As a result, as shown in FIGS. 28A, 28B, and 29, the hollow cavity 70 is formed between the epitaxial layer 50 and the support substrate 10. FIGS. 28A and 28B are cross-sectional views showing the manufacturing method subsequent to FIGS. 27A and 27B, respectively. FIG. 29 is a cross-sectional view showing the manufacturing method subsequent to FIG. 25B.

At the time of formation, the epitaxial layer 50 is supported by the silicon pillars 40 on the support substrate 10 as shown in FIG. 29. Therefore, the epitaxial layer 50 does not fall into the support substrate 10.

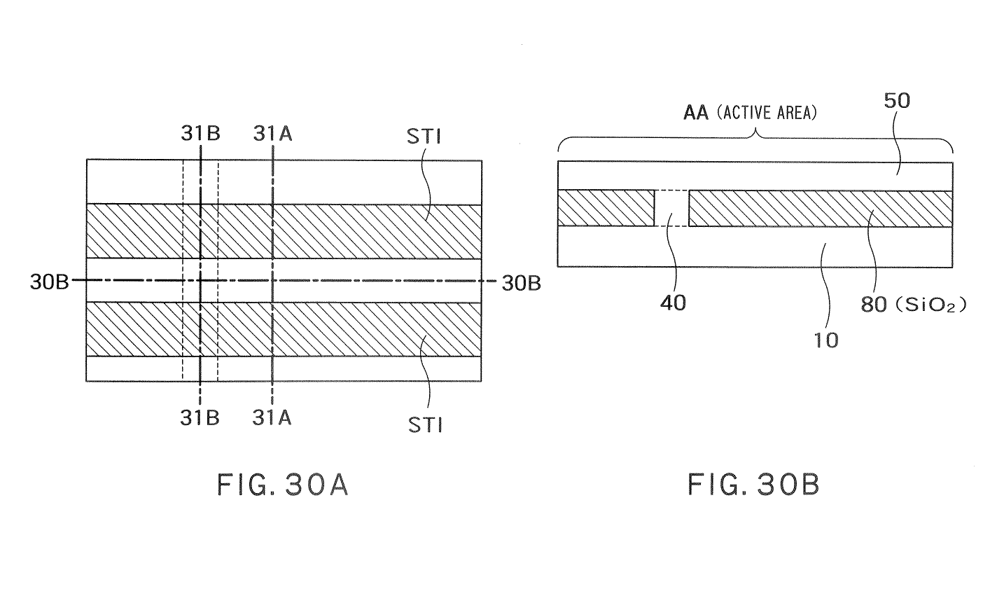

As shown in FIGS. 30A and 30B, the insulating film 80 is filled up into the cavity 70 by the LPCVD or the like. FIG. 30B is a cross-sectional view taken along a line 30B-30B of FIG. 30A. In this manner, the active area other than the regions of the STI regions and the silicon pillars 40 has the SOI structure.

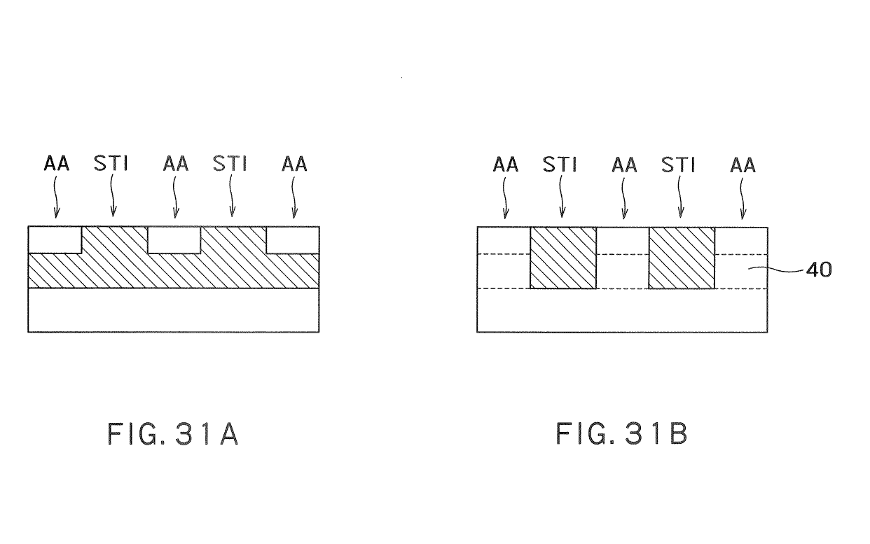

FIGS. 31A and 31B are cross-sectional views taken along lines 31A-31A and 31B-31B of FIG. 30A, respectively. An active area AA is formed between the adjacent STI regions.

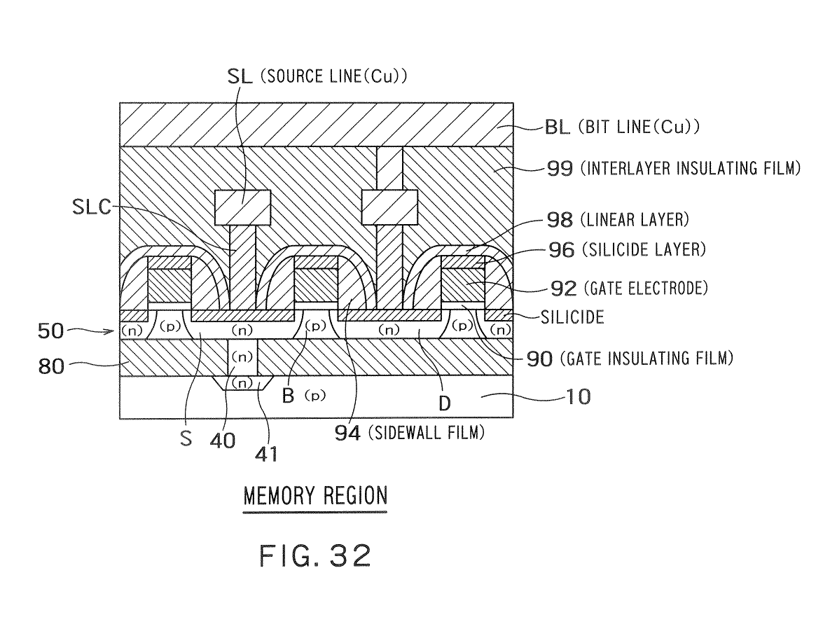

Thereafter, memory cells are formed in the active area AA using a known method. Accordingly, a structure shown in FIG. 32 can be obtained. The FBC memory device according to the third embodiment includes the n-type silicon pillars 40 and n-type diffused layers 41 which have an opposite conductivity-type of the p-type support substrate 10. A pn junction is formed between each n-type diffused layers 41 and the p-type support substrate 10. Therefore, by setting a substrate potential lower than a source potential, the source layer S is electrically disconnected from the support substrate 10. Accordingly, the silicon pillars 40 and the diffused layers 41 do not influence the FBC memory device. Other configurations according to the third embodiment can be the same as those according to the first embodiment.

In the third embodiment, there is no need to form the dedicated photolithography mask to forming the openings. In addition, because the openings and the trenches are formed in the same process, the manufacturing process becomes shorter than those according to the first and second embodiments. Moreover, the third embodiment can exhibit the same advantages as those of the first embodiment.

### Fourth Embodiment

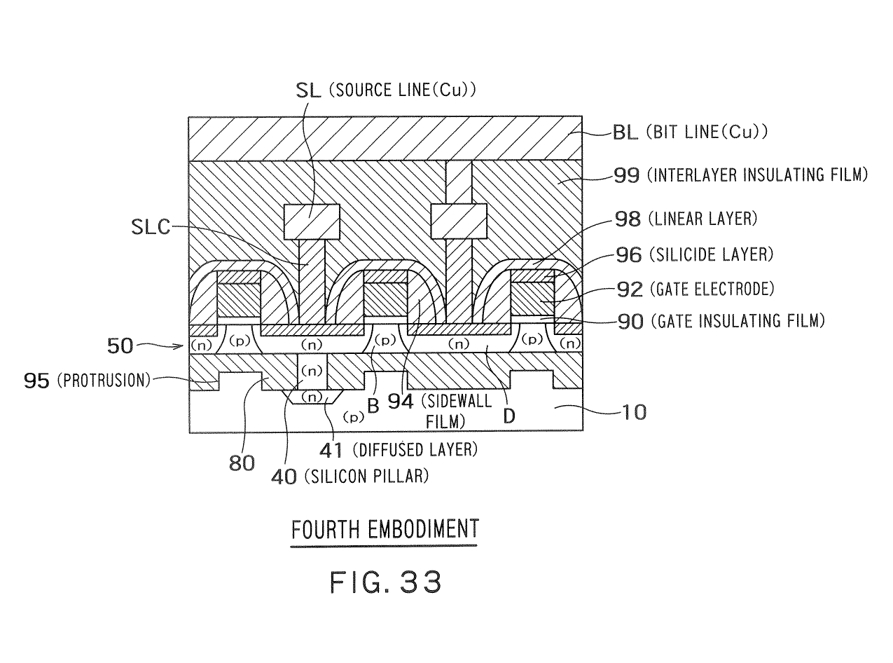

FIG. 33 is a cross-sectional view of an FBC memory device according to a fourth embodiment of the present invention. The fourth embodiment is a combination of the second embodiment with the third embodiment. Therefore, the FBC memory device according to the fourth embodiment includes the protrusions 95, the silicon pillars 40, and the diffused layers 41. A plan view of the FBC memory device according to the fourth embodiment is the same as the plan view shown in FIG. 12. Furthermore, the cross section taken along the line 14-14 of FIG. 12 is the same as the cross section shown in FIG. 14. The fourth embodiment can exhibit advantages of both the second and third embodiments.

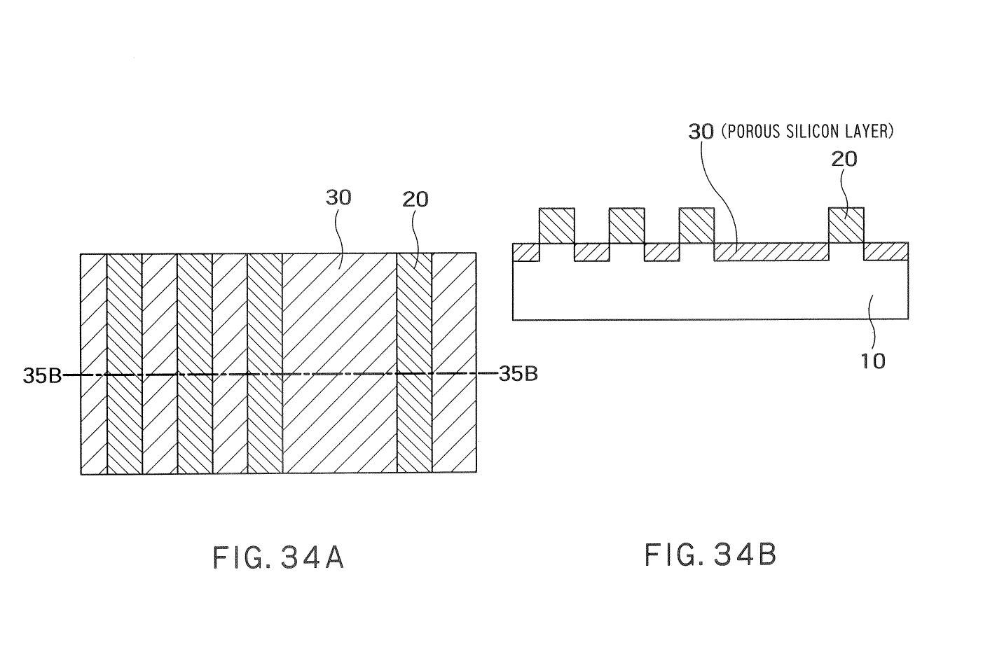

FIGS. 34A to 42B are plan views or cross-sectional views showing a manufacturing method of the FBC memory device according to the fourth embodiment. FIGS. 34A, 35A, 36A, 37, and 41A are plan views, and FIGS. 34B, 35B, 36B, 38A to 40, 41B, 42A, and 42B are cross-sectional views. Since a logic circuit element according to the fourth embodiment is the same as the logic circuit element according to the first embodiment, the logic circuit element according to the fourth embodiment will not be shown and explained herein.

First, similarly to the first embodiment, the support substrate 10 is prepared and the insulating film 20 serving as the mask material is formed on the support substrate 10. At the time of formation, the insulating film 20 is formed into a line shape on the regions for forming the source lines SL and the body region B.

Next, the surface region of the support substrate 10 is anodized using the insulating film 20 as a mask (first porous layer formation). As a result, as shown in FIGS. 34A and 34B, the surface region of the support substrate 10 is transformed into the porous silicon layer 30, and the porous silicon layer 30 is formed into the first pattern. FIG. 34B is a cross-sectional view taken along a line 35B-35B of FIG. 34A.

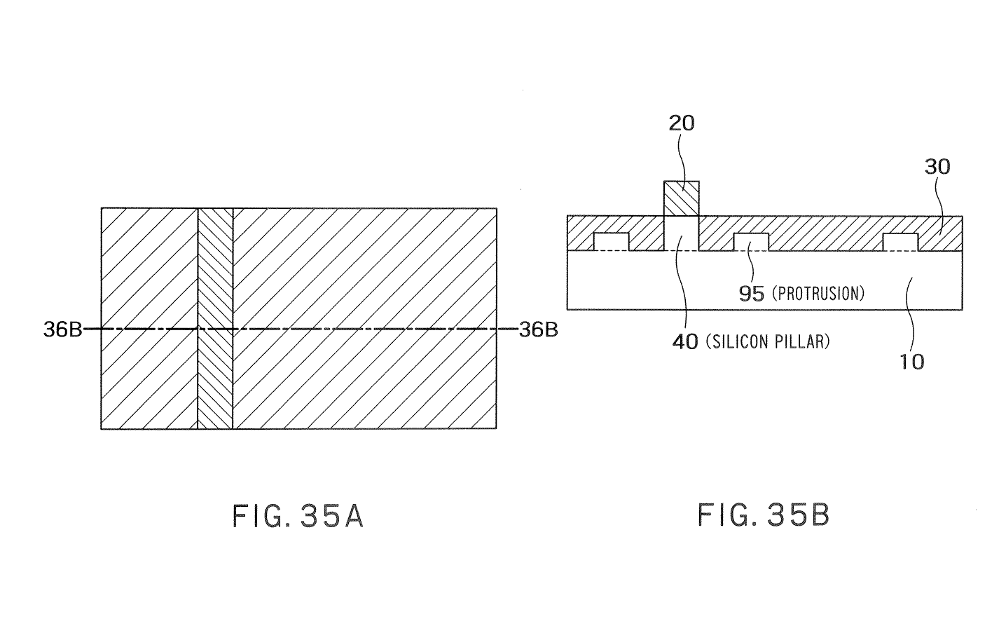

Using the lithography and the etching, the insulating film 20 above the regions for forming the protrusions 95 is removed while leaving the insulating film 20 on the regions for forming the silicon pillars 40. Using the insulating film 20 as a mask, the surface region of the support substrate 10 is anodized (second porous layer formation). As a result, as shown in FIGS. 35A and 35B, the porous state of the surface region of the support substrate 10 that is not covered with the insulating film 20 is further accelerated. FIG. 35B is a cross-sectional view taken along a line 36B-36B of FIG. 35A. Therefore, similarly to the second embodiment, the porous silicon layer 30 in the first pattern (the active area in the memory region) is formed relatively thick by the second porous layer formation. The porous silicon layer 30 in the first pattern is relatively thick. The surface region of the support substrate 10 in the pattern of the protrusions 95 is subjected only to the second porous layer formation. Therefore, the porous silicon layer 30 in the pattern of the protrusions 95 is relatively thin. Moreover, because the regions for forming the silicon pillars 40 are covered with the insulating film 20, the surface region of the support substrate 10 in the pattern of the silicon pillars 40 is not transformed into the porous silicon layer 30.

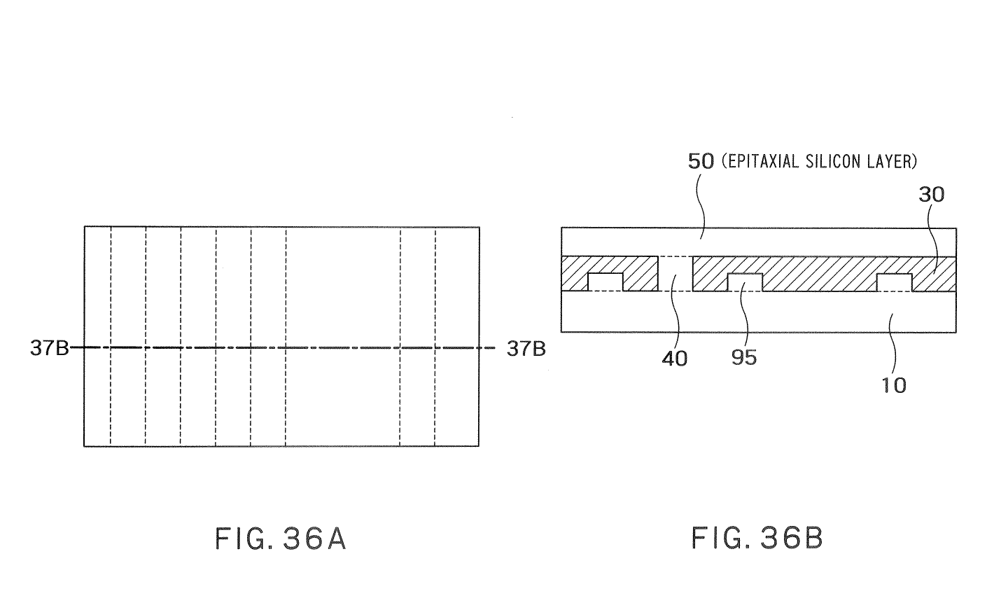

After removing the insulating film 20, the epitaxial layer 50 is formed on the porous silicon layer 30 and the silicon pillars 40 by the epitaxial growth as shown in FIGS. 36A and 36B. FIG. 36B is a cross-sectional view taken along a line 37B-37B of FIG. 36A.

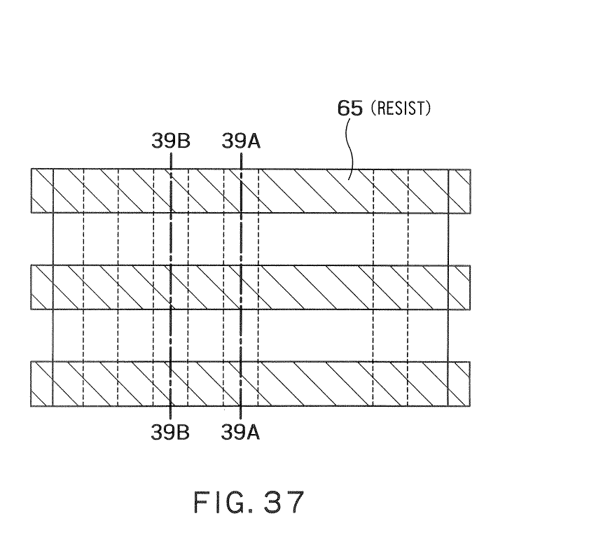

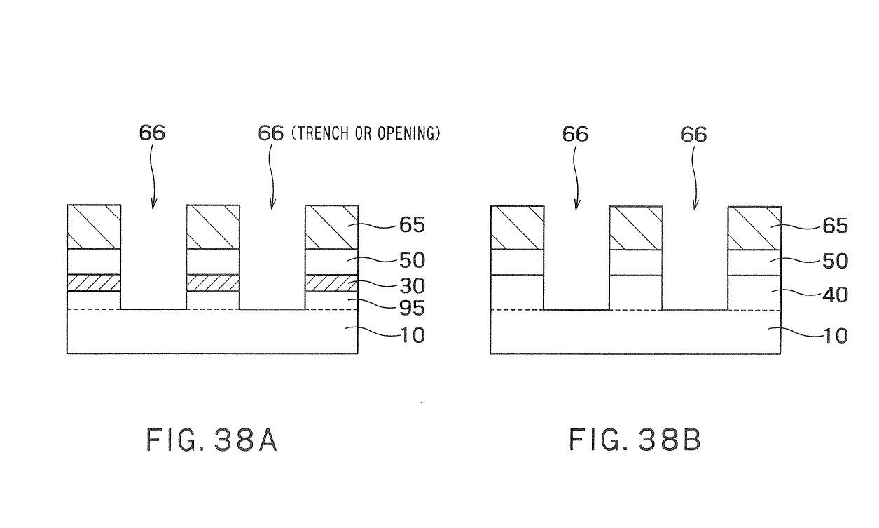

As shown in FIG. 37, the active area of the epitaxial layer 50 is covered with the resist 65. Using the RIE or the like, the epitaxial layer 50 and the silicon pillars 40 in the element isolation region are removed, thereby forming trenches or openings 66. FIG. 38A is a cross-sectional view taken along a line 39A-39A of FIG. 37 after formation of the trenches or openings 66. FIG. 38B is a cross-sectional view taken along a line 39B-39B of FIG. 37 after formation of the trenches or openings 66. The trenches or openings 66 are employed as openings to remove the porous silicon layer 30 and then as trenches to form the STI regions. Therefore, the fourth embodiment can exhibit the same advantages as those of the third embodiment.

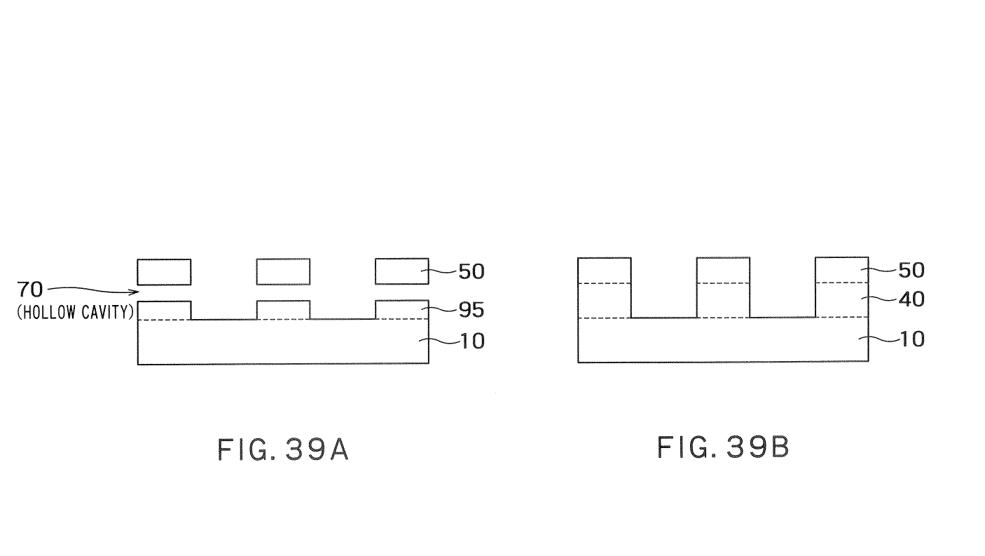

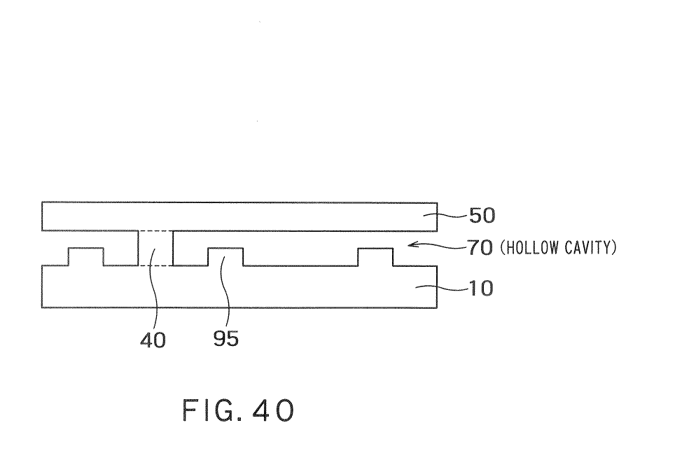

The porous silicon layer 30 is isotropically etched through the trenches or openings 66 using the hydrofluoric-acid-based solution (e.g., HF+H₂O₂ solution). As a result, as shown in FIGS. 39A, 39B and 40, the hollow cavity 70 is formed between the epitaxial layer 50 and the support substrate 10. FIGS. 39A and 39B are cross-sectional views showing the manufacturing method subsequent to FIGS. 38A and 38B, respectively. FIG. 40 is a cross-sectional view showing the manufacturing method subsequent to FIG. 36B.

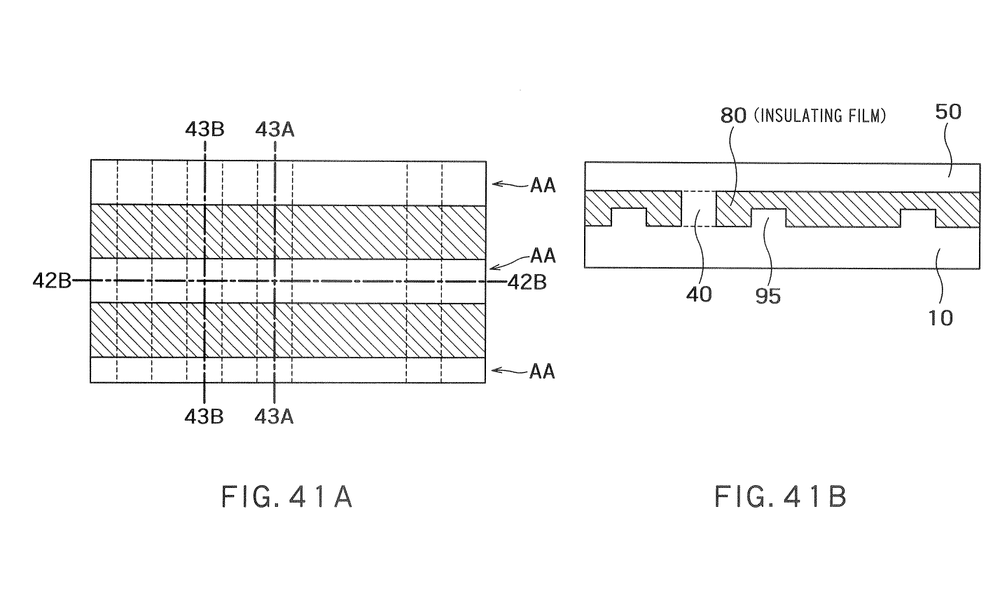

As shown in FIGS. 41A and 41B, the insulating film 80 is filled up into the cavity 70 through the openings 60 by the LPCVD or the like. FIG. 41B is a cross-sectional view taken along a line 42B-42B of FIG. 41A. In this manner, the active area other than the regions of the STI regions and the silicon pillars 40 has the SOI structure.

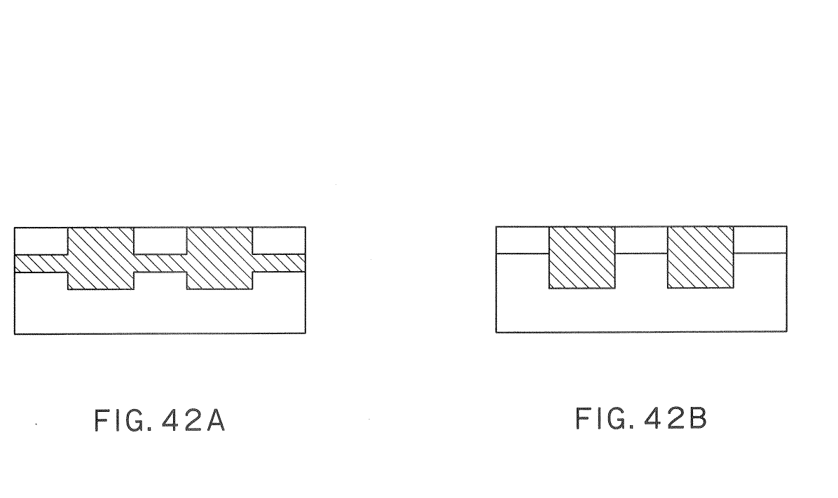

FIGS. 42A and 42B are cross-sectional views taken along lines 43A-43A and 43B-43B of FIG. 41A, respectively. Thereafter, memory cells are formed in the active area AA using a well-known method. As a result, the structure shown in FIG. 33 can be obtained.

### Fifth Embodiment

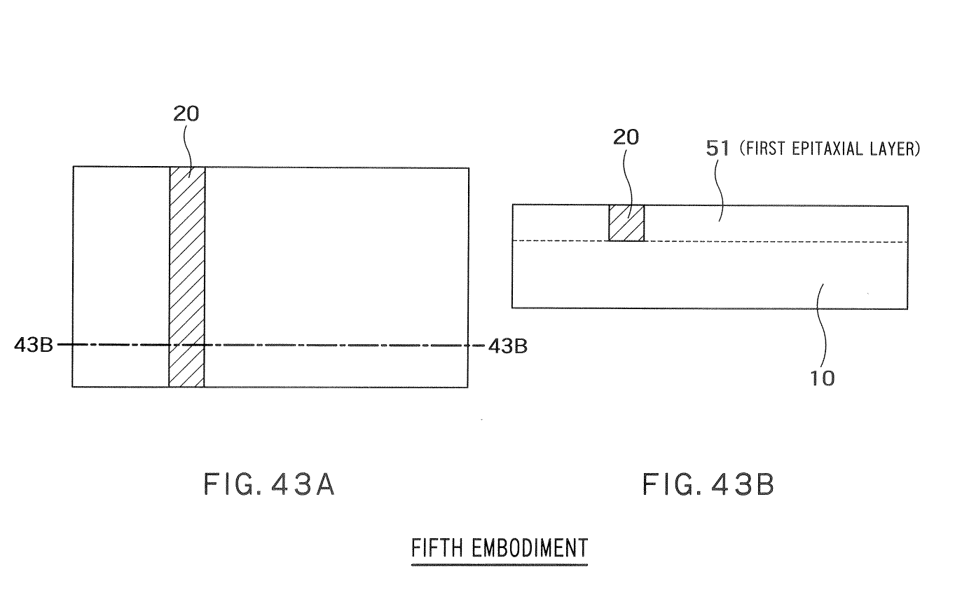

FIGS. 43A to 49 are plan views or cross-sectional views showing a manufacturing method of an FBC memory device according to a fifth embodiment of the present invention. FIGS. 43A, 44A, 45A, and 46 are plan views, and FIGS. 43B, 44B, 45B, and 47B to 49 are cross-sectional views. A logic circuit element according to the fifth embodiment is the same as the logic circuit element according to the first embodiment.

First, similarly to the first embodiment, the support substrate 10 is prepared and the insulating film 20 serving as the mask material is formed on the support substrate 10. At the time of formation, the insulating film 20 is formed into a line shape on the regions for forming the source lines SL. The insulating film 20 is not formed in the logic region.

Next, as shown in FIGS. 43A and 43B, a first epitaxial layer 51 is formed on the surface region of the support substrate 10 using the insulating film 20 as a mask. FIG. 43B is a cross-sectional view taken along a line 43B-43B of FIG. 43A. At the time of forming the first epitaxial layer 51, the first epitaxial layer 51 is formed directly on the support substrate 10 in the logic region because lack of the insulating film 20.

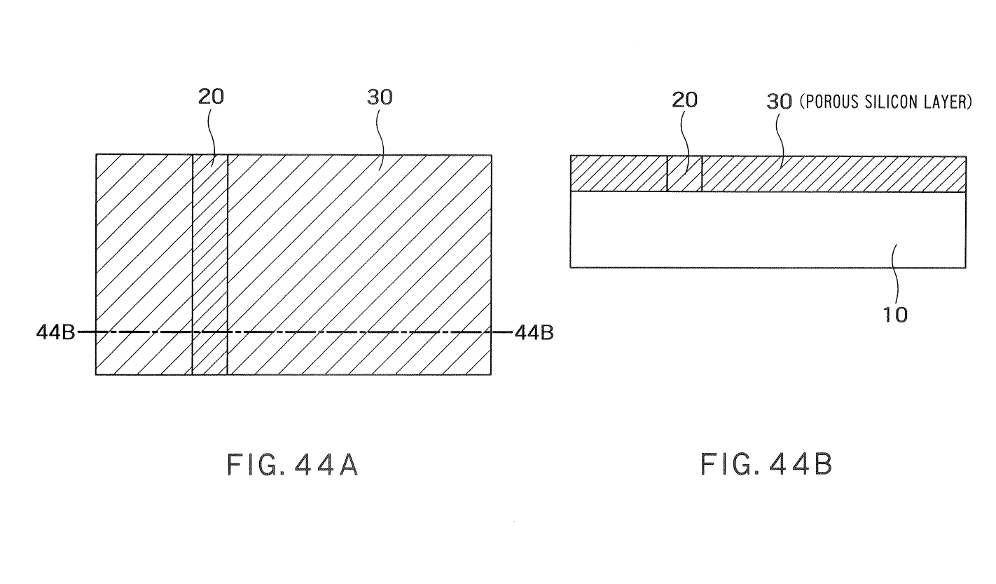

The surface region of the support substrate 10 is anodized. As a result, as shown in FIGS. 44A and 44B, the first epitaxial layer 51 is transformed into the porous silicon layer 30. FIG. 44B is a cross-sectional view taken along a line 44B-44B of FIG. 44A.

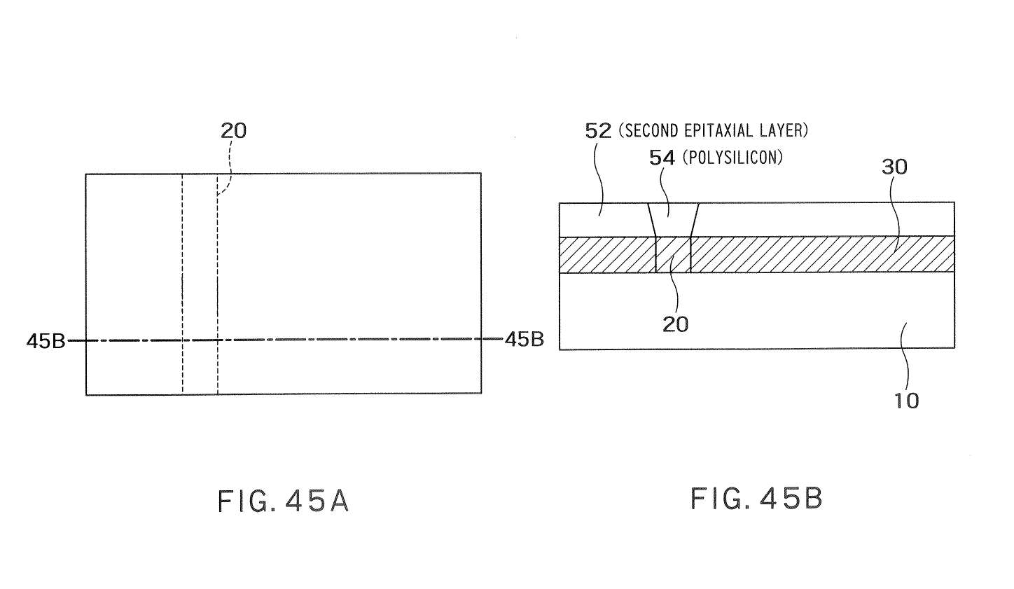

As shown in FIGS. 45A and 45B, a second epitaxial layer 52 is formed on the porous silicon layer 30 by the epitaxial growth, and polysilicon 54 is formed on the insulating film 20. As the epitaxial growth, selective epitaxial growth (SEG) can be used. If the SEG is used, the second epitaxial layer 52 is also formed on the insulating film 20. FIG. 45B is a cross-sectional view taken along a line 45B-45B of FIG. 45A. To suppress increase in a resistance between the source layer S and the source-line contact SLC, a surface area of the polysilicon 54 is preferably smaller than a diameter of the source-line contact SLC. In the logic region, the second epitaxial layer 52 is formed on the first epitaxial layer 51.

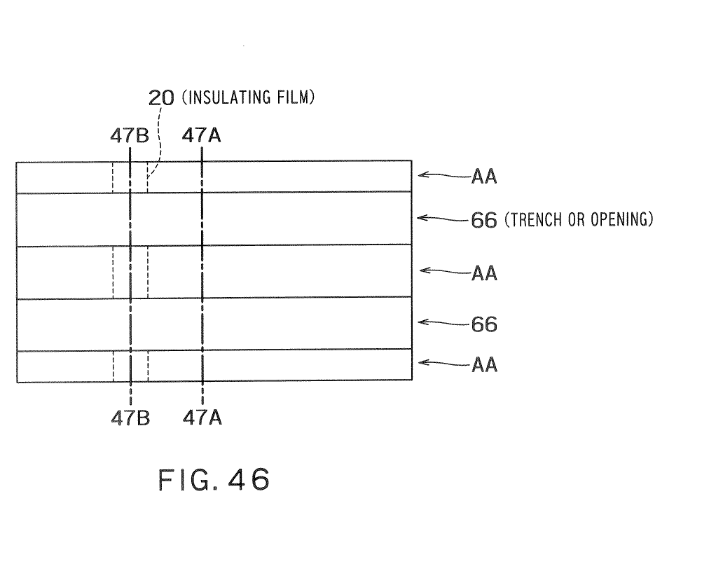

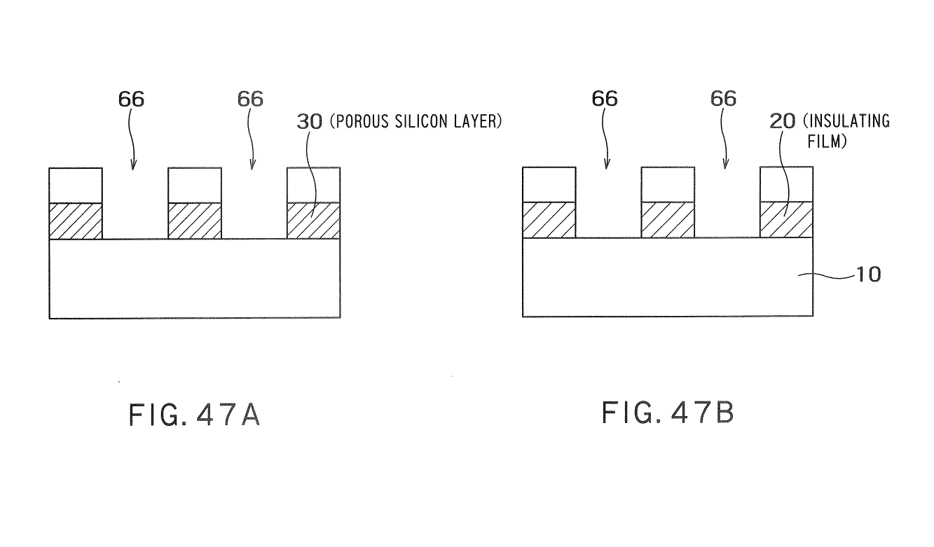

Using the lithography and the RIE, the openings or trenches 66 are formed in the element isolation regions. FIG. 47A is a cross-sectional view taken along a line 47A-47A of FIG. 46 after formation of trenches. FIG. 47B is a cross-sectional view taken along a line 47B-47B of FIG. 46 after formation of the trenches. The trenches or openings 66 are employed as openings to remove the porous silicon layer 30 and then as trenches to form the STI regions. Therefore, the fifth embodiment can exhibit the same advantages as those of the third embodiment.

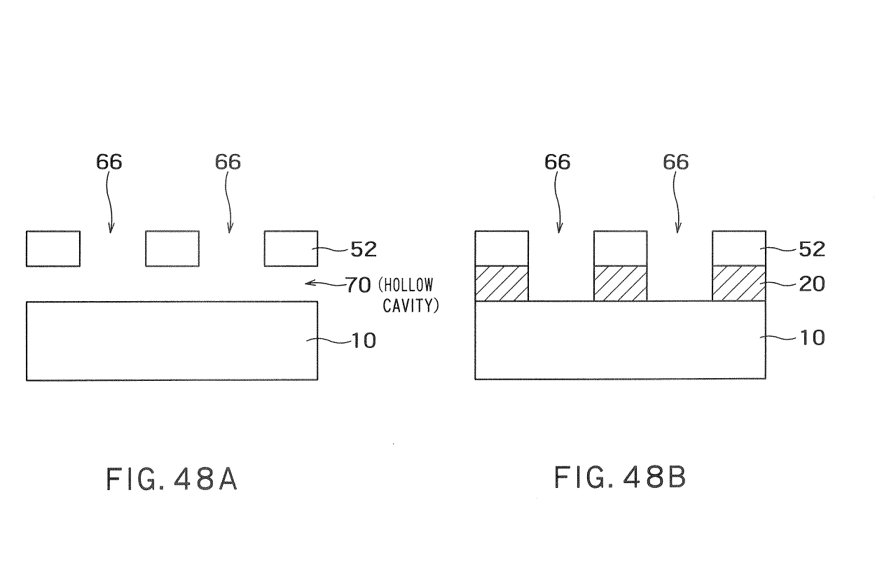

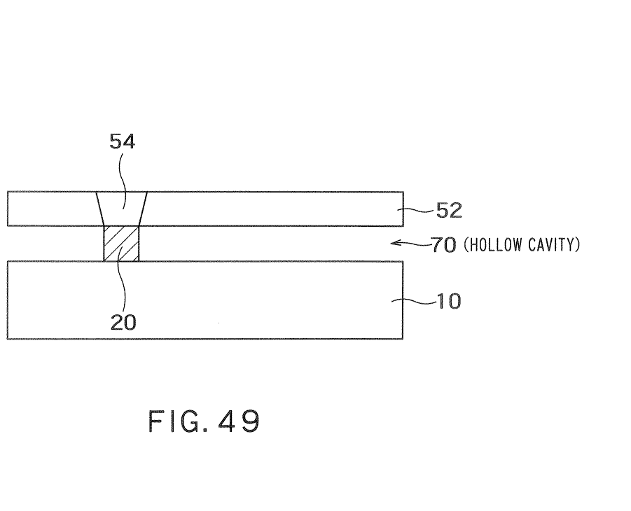

The porous silicon layer 30 is isotropically etched through the openings or trenches 66 using the hydrofluoric-acid-based solution (e.g., HF-H₂O₂ solution). As a result, as shown in FIGS. 48A and 49, the hollow cavity 70 is formed between the second epitaxial layer 52 and the support substrate 10. FIGS. 48A and 48B are cross-sectional views showing the manufacturing method subsequent to FIGS. 47A and 47B, respectively. FIG. 49 is a cross-sectional view showing the manufacturing method subsequent to FIG. 45B. As shown in FIGS. 48B and 49, the insulating film 20 remains without being removed. In the fifth embodiment, the insulating film 20 functions as support pillars of the second epitaxial layer 52 (insulating film pillars) to replace the silicon pillars 40. As the insulating film 20, a silicon oxide film or a silicon nitride film, for example, can be used.

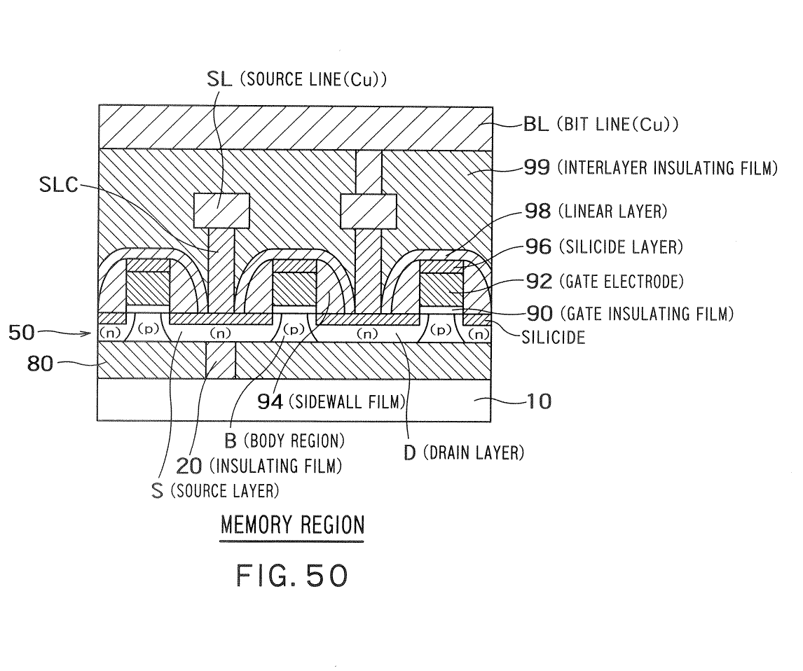

In the fifth embodiment, similarly to the other embodiments, the insulating film 80 is filled up into the cavity 70 through the trenches or openings 66 by the LPCVD or the like. Thereafter, memory cells are formed in the active area AA using the known method. A structure shown in FIG. 50 can be thereby obtained.

In the fifth embodiment, the insulating film pillars 20 are formed in place of the silicon pillars 40 in the third embodiment. The fifth embodiment can thereby exhibit the same advantages as those of the third embodiment.

In the logic circuit region according to the fifth embodiment, the first epitaxial layer 51 and the second epitaxial layer 52 are formed without providing the insulating film 20. In the porous layer forming process, the first epitaxial layer 51 is covered with the resist. As a result, a bulk substrate in which the support substrate 10, the first epitaxial layer 51, and the second epitaxial layer 52 are integrated is provided. By forming the logic circuit element on the bulk substrate, the logic circuit element can be formed at the same height or level as that of the memory cells.

### Sixth Embodiment

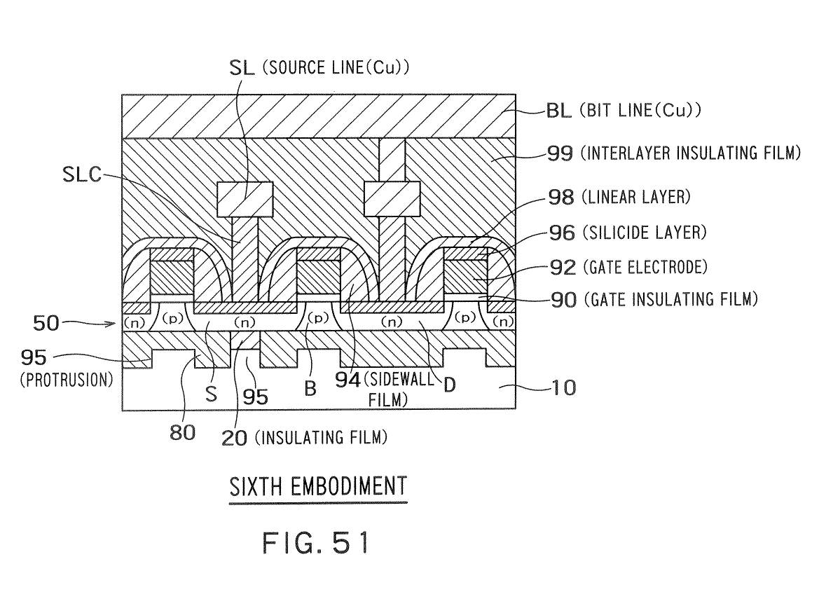

FIG. 51 is a cross-sectional view of an FBC memory device according to a sixth embodiment of the present invention. The sixth embodiment is a combination of the second embodiment with the fifth embodiment. However, differently from the second embodiment, the protrusions 95 are formed not only below the body region B but also below the insulating film pillars 20 (source layers S). Other configurations according to the sixth embodiment are the same as those according to the second or fifth embodiment. The sixth embodiment can thereby attain the same advantages as those of the second and fifth embodiment.

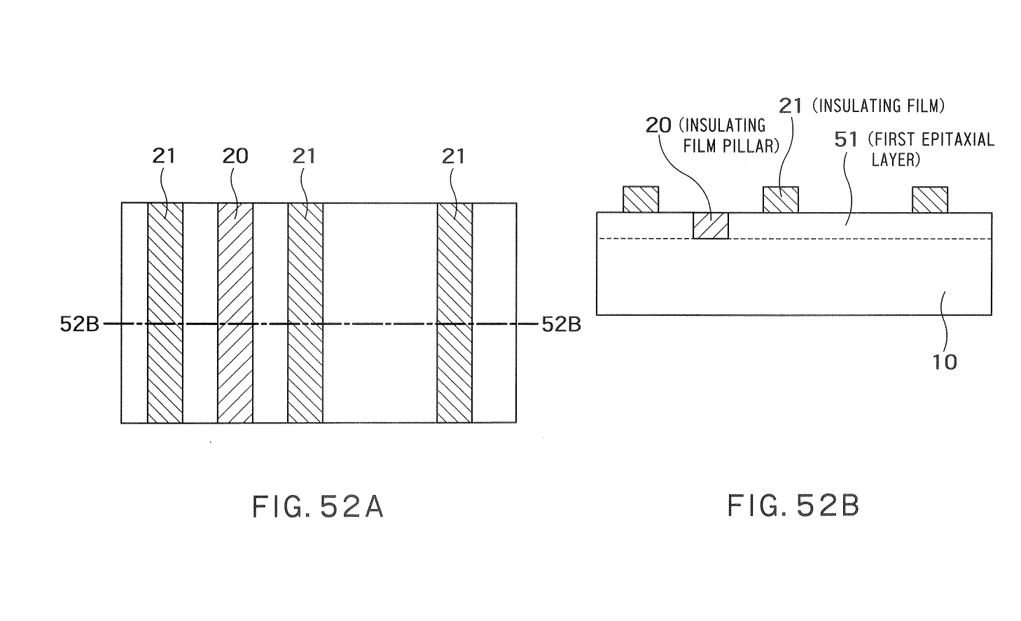

FIGS. 52A to 59 are plan views or cross-sectional views showing a manufacturing method of the FBC memory device according to the sixth embodiment. FIGS. 52A, 53A, 54A, and 56 are plan views, and FIGS. 52B, 53B, 54B, 55, and 57A to 59 are cross-sectional views. A logic circuit element according to the sixth embodiment is the same as the logic circuit element according to the first embodiment.

First, similarly to the first embodiment, the support substrate 10 is prepared and the insulating film pillar 20 is formed on the support substrate 10. At the time of formation, the insulating film pillar 20 is formed into a line shape on the regions for forming the source lines SL.

Next, as shown in FIGS. 52A and 52B, the first epitaxial layer 51 is formed on the surface region of the support substrate 10 using the insulating film 20 as a mask. FIG. 52B is a cross-sectional view taken along a line 52B-52B of FIG. 52A. An insulating film 21 is then formed on the line of the first epitaxial layer 51. The insulating film 21 is formed in the region for forming the body region B.

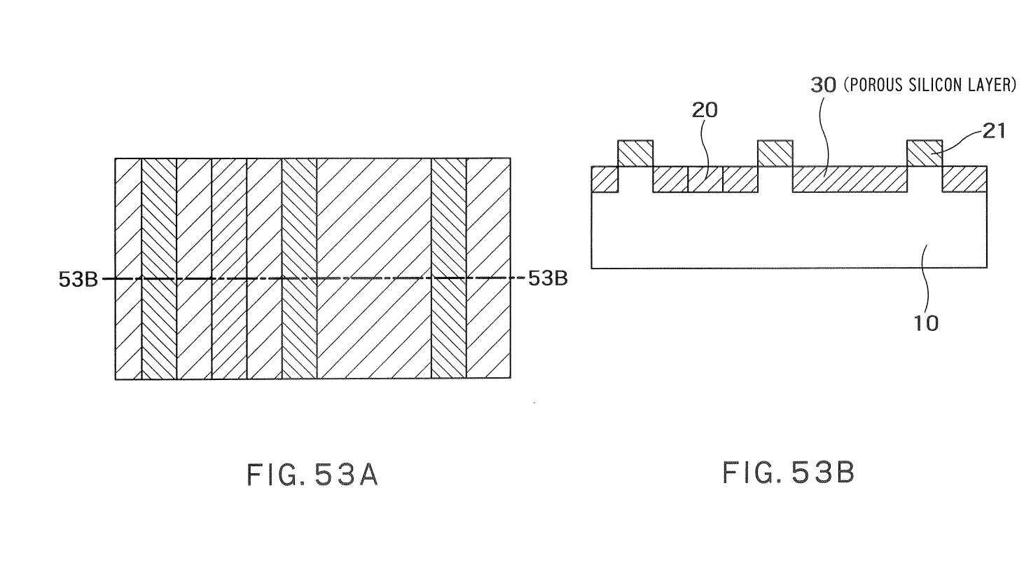

Next, the surface region of the support substrate 10 is anodized (at first porous layer formation) using the insulating film pillars 20 and the insulating film 21. As a result, as shown in FIGS. 53A and 53B, the first epitaxial layer 51 is transformed into the porous silicon layer 30. FIG. 53B is a cross-sectional view taken along a line 53B-53B of FIG. 53A. It is assumed that the plan pattern of the porous silicon layer 30 formed by the first porous layer formation is the first pattern.

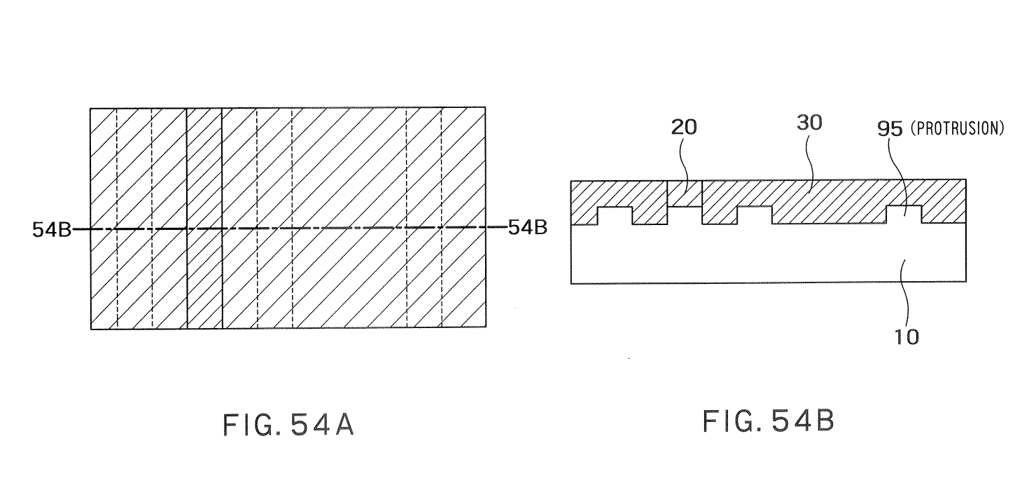

After removing the insulating film 21, the surface region of the support substrate 10 is anodized using the insulating film 20 as a mask (the second porous layer formation). As a result, as shown in FIGS. 54A and 54B, the porous state of the surface region of the support substrate 10 that is not covered with the insulating film 20 is further accelerated. FIG. 54B is a cross-sectional view taken along a line 54B-54B of FIG. 54A. It is assumed that the plan pattern of the porous silicon layer 30 formed at the second porous layer formation is the second pattern. The first pattern overlaps with the second pattern in a periphery region of the insulating film 20. Further, the first pattern also overlaps with the second pattern in the region of the insulating film 20 (in the source formation region). Because the insulating film 20 is not transformed into porous silicon by anodization. Therefore, the protrusion 95 made of a semiconductor material is formed under the insulating film 20.

The surface region of the support substrate 10 in the first pattern (the active area in the memory region) is subjected to both the first porous layer formation and the second porous layer formation. Therefore, the porous silicon layer 30 in the first pattern is relatively thick. The surface region of the support substrate 10 in the pattern of the protrusions 95 is subjected only to the second porous layer formation. Therefore, the porous silicon layer 30 in the pattern of the protrusions 95 is relatively thin. Moreover, the support substrate 10 in the pattern of the insulating film pillars 20 is not transformed into the porous silicon layer 30.

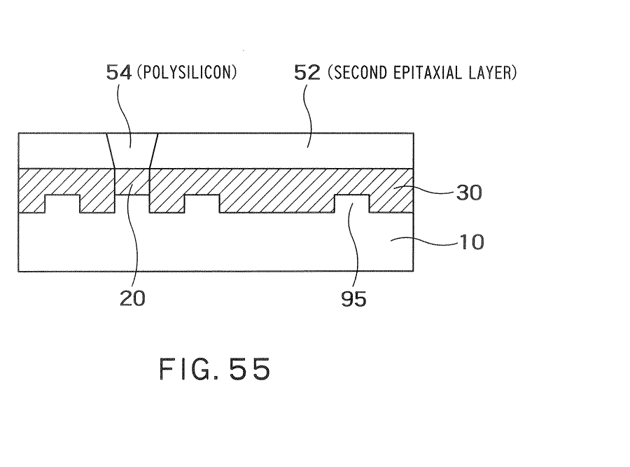

As shown in FIG. 55, the second epitaxial layer 52 is formed on the porous silicon layer 30 by the epitaxial growth, and the polysilicon 54 is formed on the insulating film 20. As the epitaxial growth, selective epitaxial growth (SEG) can be used. If the SEG is used, the second epitaxial layer 52 is also formed on the insulating film 20. To suppress increase in the resistance between the source layer S and the source-line contact SLC, the surface area of the polysilicon 54 is preferably smaller than the diameter of the source-line contact SLC.

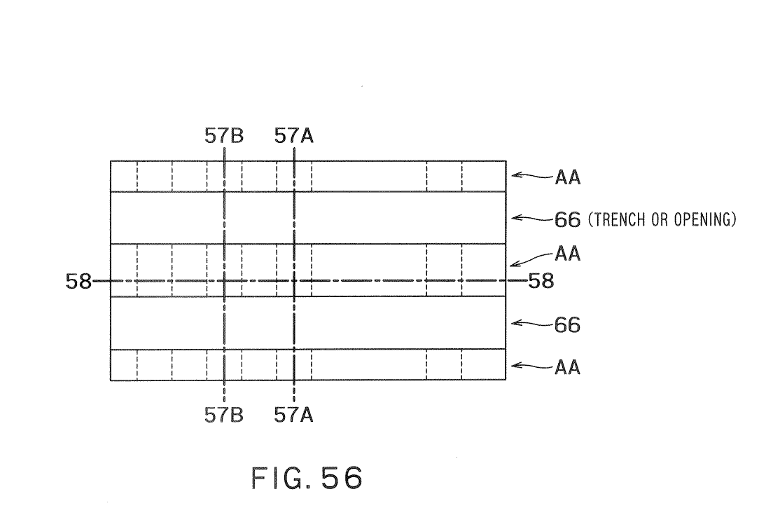

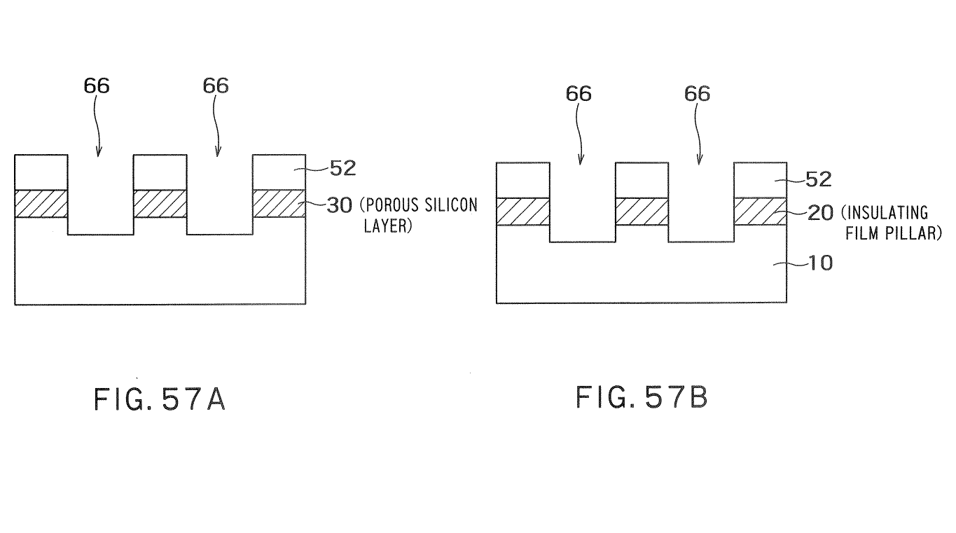

As shown in FIG. 56, using the lithography and the RIE, the openings or trenches 66 are formed for the STI regions in the element isolation regions. FIG. 57A is a cross-sectional view taken along a line 57A-57A of FIG. 56 after formation of the opening or trenches 66. FIG. 57B is a cross-sectional view taken along a line 57B-57B of FIG. 56 after formation of the opening or trenches 66. The trenches or openings 66 are employed as openings to remove the porous silicon layer 30 and then as trenches to form the STI regions. Therefore, the sixth embodiment can exhibit the same advantages as those of the third embodiment.

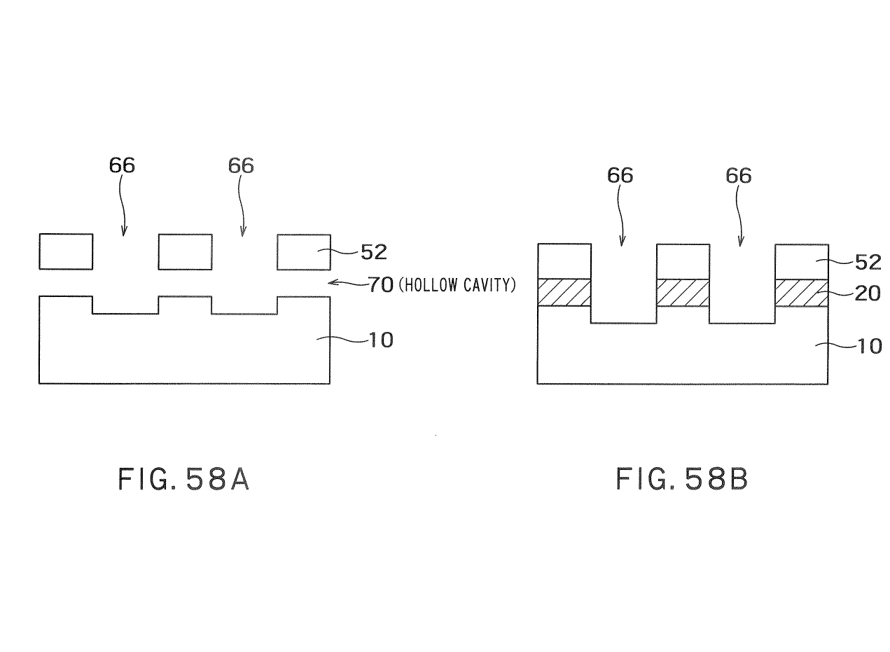

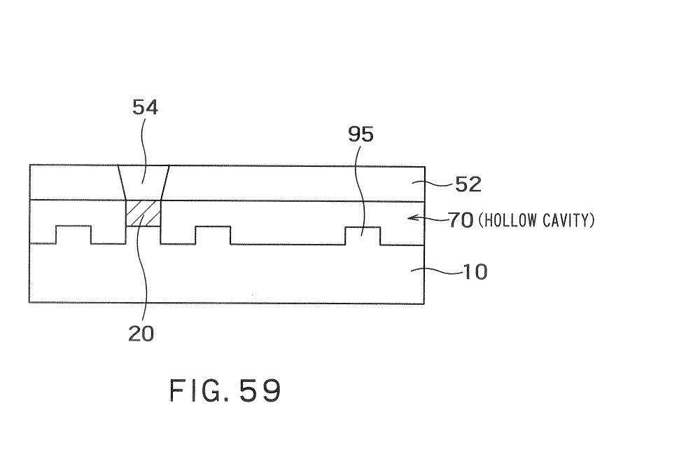

The porous silicon layer 30 is isotropically etched through the openings or trenches 66 using the hydrofluoric-acid-based solution. As a result, as shown in FIGS. 58A and 59, the hollow cavity 70 is formed between the second epitaxial layer 52 and the support substrate 10. FIGS. 58A and 58B are cross-sectional views showing the manufacturing method subsequent to FIGS. 57A and 57B, respectively. FIG. 59 is a cross-sectional view showing the manufacturing method subsequent to FIG. 55. In the sixth embodiment, the insulating film pillars 20 function as support pillars of the second epitaxial layer 52 similarly to the fifth embodiment.

Similarly to the first to fifth embodiments, the insulating film 80 is filled up into the cavity 70 through the trenches or openings 66 by the LPCVD or the like. Thereafter, memory cells are formed in the active area AA using the known method. A structure shown in FIG. 51 can be thereby obtained. The sixth embodiment can, therefore, exhibit the same advantages as those of the second and fifth embodiments.

In the logic region according to the sixth embodiment, the bulk substrate in which the support substrate 10, the first epitaxial layer 51, and the second epitaxial layer 52 are integrated is provided. At the first and second porous layer formations, the first epitaxial layer 51 is covered with the resist. By doing so, the logic circuit element can be formed at the same height or level as that of the memory cells.

### Seventh Embodiment

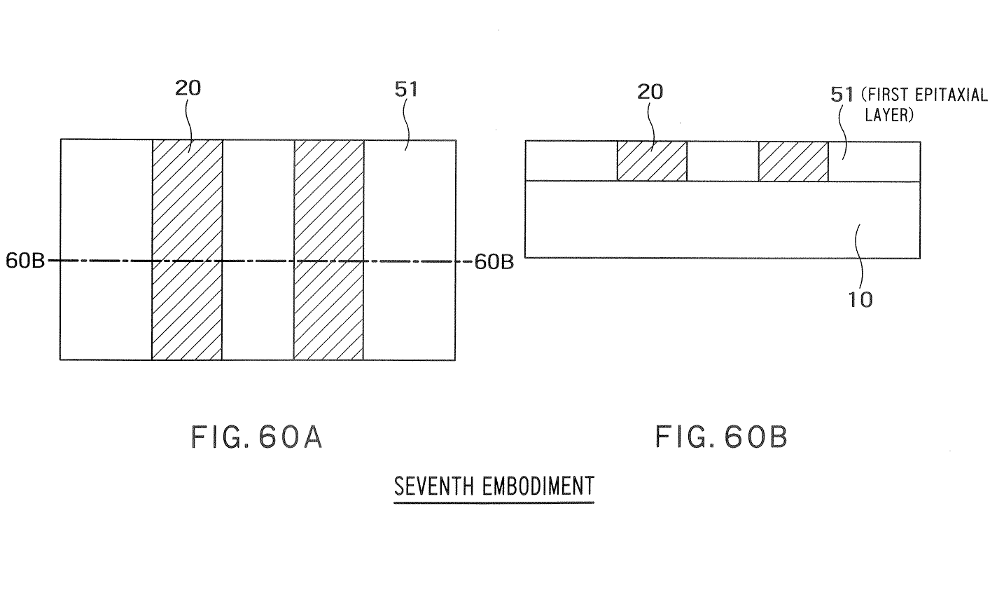

FIGS. 60A to 66 are plan views or cross-sectional views showing a manufacturing method of an FBC memory device according to a seventh embodiment of the present invention. FIGS. 60A, 61A, and 63 are plan views, and FIGS. 60B, 61B, 62, and 64A to 66 are cross-sectional views. A logic circuit element according to the seventh embodiment is the same as the logic circuit element according to the first embodiment.

First, similarly to the first embodiment, the support substrate 10 is prepared and the insulating film pillars 20 are formed on the support substrate 10. At the time of formation, the insulating film pillars 20 are formed into a line shape on the regions for forming the source layer S and the drain layer D.

Next, as shown in FIGS. 60A and 60B, the first epitaxial layer 51 is formed on the surface region of the support substrate 10 using the insulating film pillar 20 as a mask. FIG. 60B is a cross-sectional view taken along a line 60B-60B of FIG. 60A.

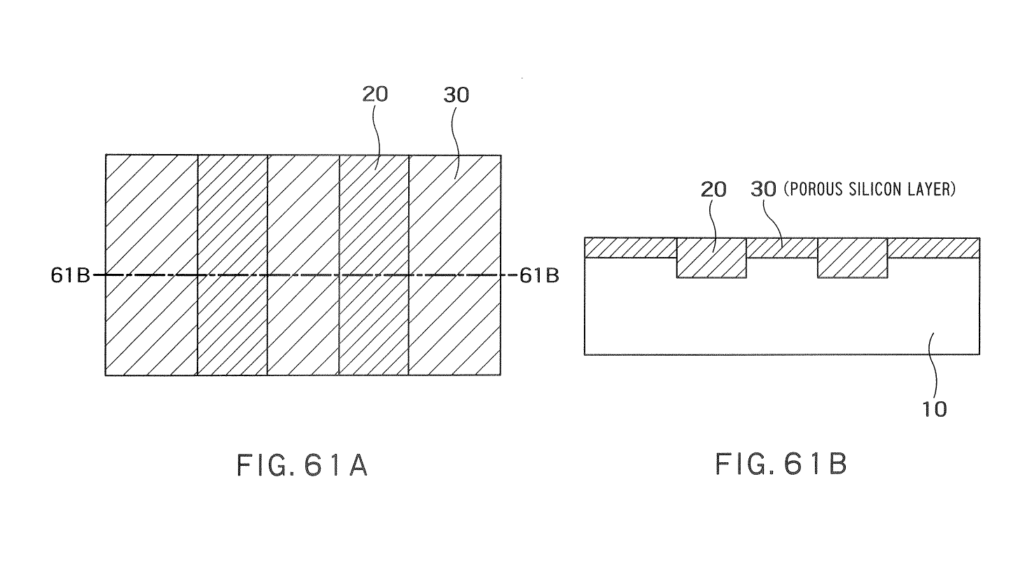

The surface region of the support substrate 10 is anodized using the insulating film pillars 20 as a mask. As a result, as shown in FIGS. 61A and 61B, the first epitaxial layer 51 is transformed into the porous silicon layer 30. FIG. 61B is a cross-sectional view taken along a line 61B-61B of FIG. 61A. The porous silicon layer 30 is thinner than the insulating film pillar 20.

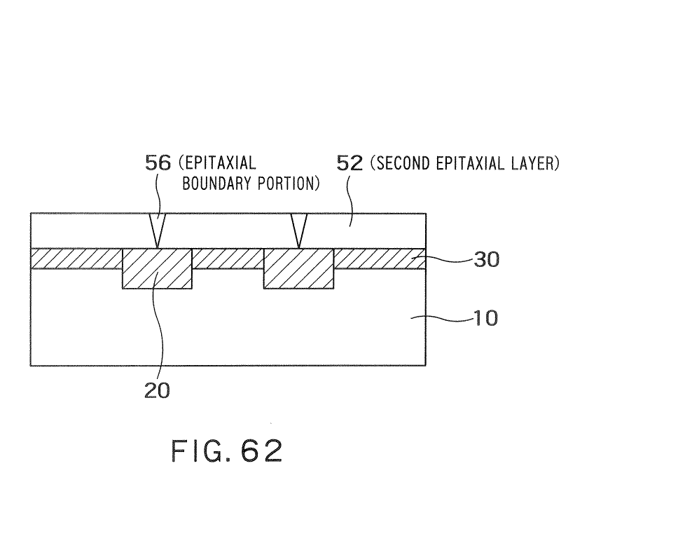

As shown in FIG. 62, the second epitaxial layer 52 is formed on the porous silicon layer 30 and the insulating film pillars 20 by the SEG. In the seventh embodiment, the second epitaxial layer 52 is also formed on the insulating film 20. To suppress increase in parasitic resistance between the source layer S and the source-line contact SLC and that between the drain layer D and the bit-line contact BLC, the surface area of a boundary between the first and second epitaxial layers 51 and 52 is preferably smaller than the diameter of the source-line contact SLC and that of the bit-line contact BLC.

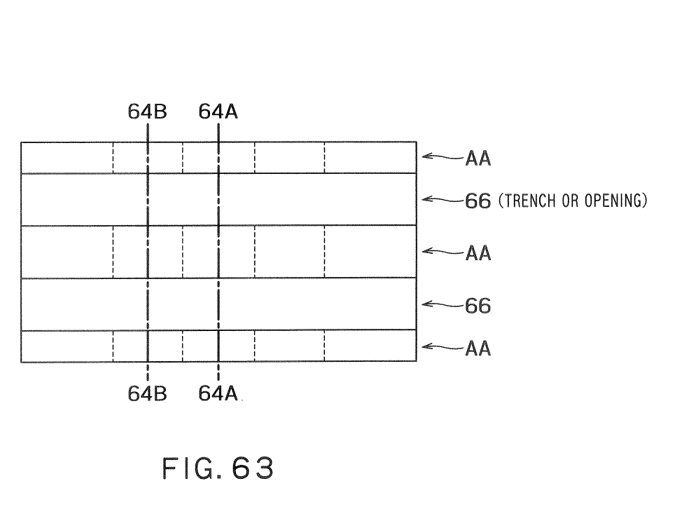

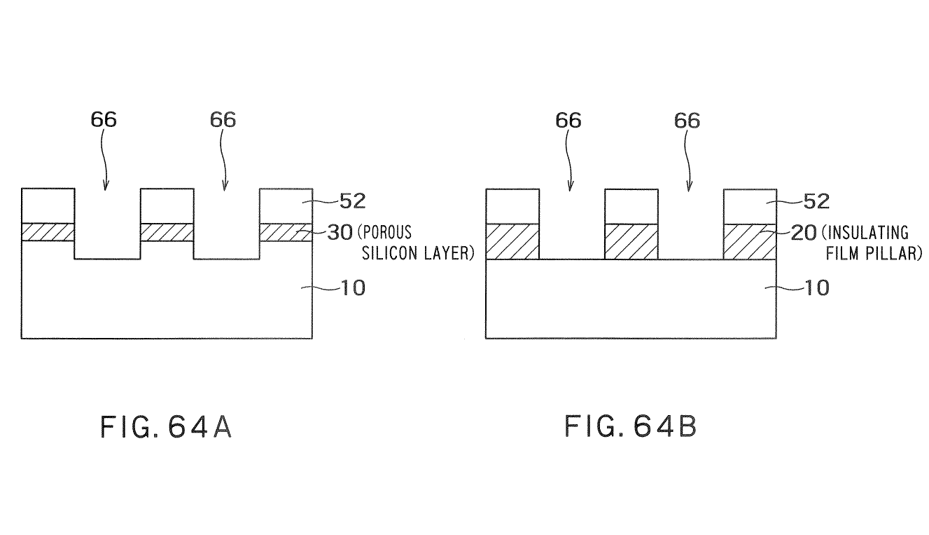

As shown in FIG. 63, using the lithography and the RIE, the openings or trenches 66 are formed in the element isolation regions for an STI region. FIG. 64A is a cross-sectional view taken along a line 64A-64A of FIG. 63. FIG. 64B is a cross-sectional view taken along a line 63B-63B of FIG. 63. The trenches or openings 66 are employed as openings to remove the porous silicon layer 30 and then as trenches to form the STI regions. Therefore, the seventh embodiment can exhibit the same advantages as those of the third embodiment.

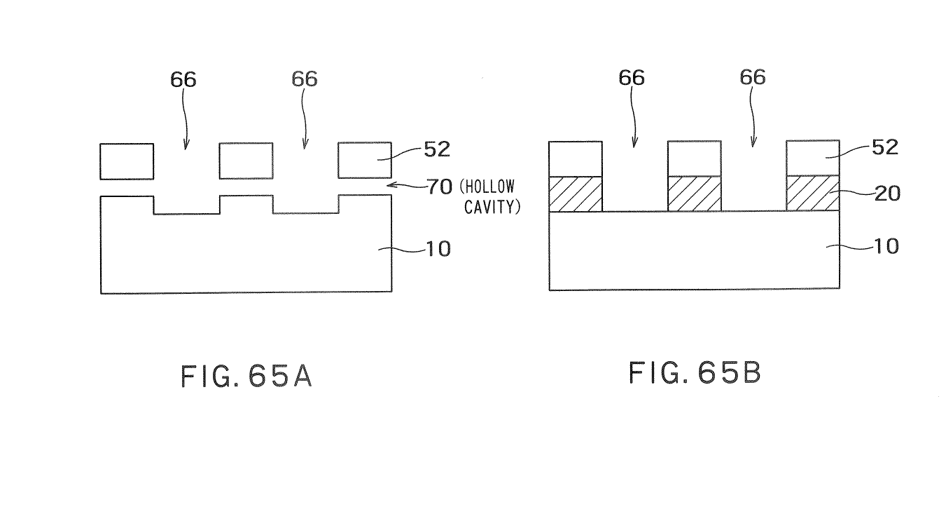

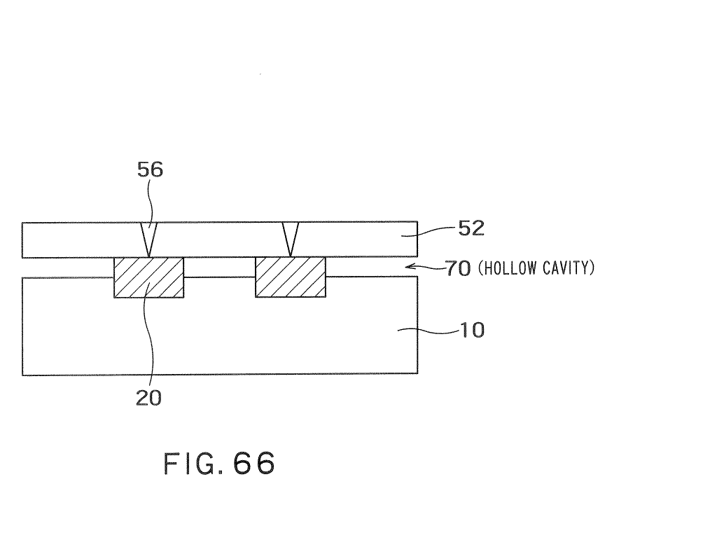

The porous silicon layer 30 is isotropically etched through the openings or trenches 66 using the hydrofluoric-acid-based solution. As a result, as shown in FIGS. 65A and 66, the hollow cavity 70 is formed between the second epitaxial layer 52 and the support substrate 10. FIGS. 65A and 65B are cross-sectional views showing the manufacturing method subsequent to FIGS. 64A and 64B, respectively. FIG. 66 is a cross-sectional view showing the manufacturing method subsequent to FIG. 62. In the seventh embodiment, the insulating film pillar 20 functions as the support pillar of the second epitaxial layer 52 similarly to the fifth embodiment.

Similarly to other embodiments, the insulating film 80 is filled up into the cavity 70 through the trenches or openings 66 by the LPCVD or the like. Thereafter, memory cells are formed in the active area AA using the known method. In the seventh embodiment, the FBC memory device includes the relatively thick insulating film pillars 20 formed below the source layer S and the drain layer D and the relatively thin insulating film 80 formed below the body region B. Therefore, the seventh embodiment can provide the FBC memory device similar in configuration to that according to the second embodiment (shown in FIG. 13).

In the logic region according to the seventh embodiment, the first epitaxial layer 51 and the second epitaxial layer 52 are formed without providing the insulating film 20 similarly to the fifth embodiment. As a result, the bulk substrate in which the support substrate 10, the first epitaxial layer 51, and the second epitaxial layer 52 are integrated is provided. By forming the logic circuit element on the bulk substrate, the logic circuit element can be formed at the same height or level as that of the memory cells.

### Eighth Embodiment

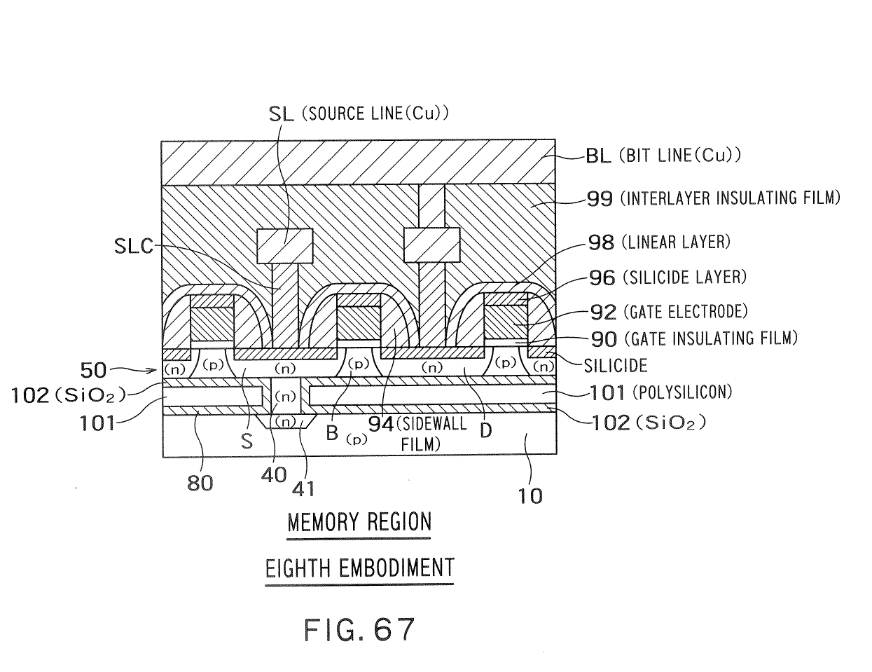

FIG. 67 is a cross-sectional view of an FBC memory device according to an eighth embodiment of the present invention. The FBC memory device according to the eighth embodiment includes an oxide film 102 formed on an inner wall of the cavity 70 and polysilicon 101 filled up into the oxide film 102. By so configuring, it is possible to further increase the capacity between the body region B and the support substrate 10, and therefore further increase the signal difference between the data “1” and the data “0”. A potential of the polysilicon 101 can function as a plate electrode.

In a manufacturing method of the FBC memory device according to the eighth embodiment, after the process shown in FIG. 29, the oxide film 102 is formed by thermally oxidizing the inner wall of the cavity 70, and the cavity 70 is filled with the polysilicon 101. Other manufacturing processes according to the eighth embodiment can be the same as those according to the third embodiment.

### Ninth Embodiment

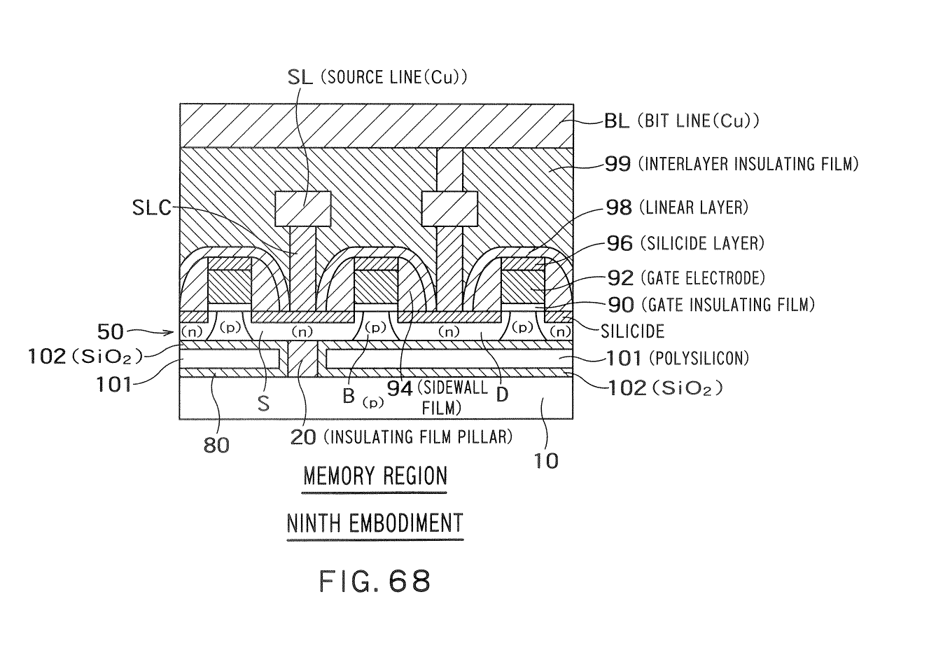

FIG. 68 is a cross-sectional view of an FBC memory device according to a ninth embodiment of the present invention. The ninth embodiment is a combination of the eighth embodiment with the fifth embodiment. Therefore, the FBC memory device according to the ninth embodiment includes the oxide film 102 and the polysilicon 101 in the cavity 70, and the insulating pillar 20 below each source layer S. The ninth embodiment can exhibit the same advantages as those of the fifth and eighth embodiments.

In a manufacturing method of the FBC memory device according to the ninth embodiment, after the process shown in FIG. 49, the oxide film 102 is formed by thermally oxidizing the inner wall of the cavity 70, and the cavity 70 is filled with the polysilicon 101. Other manufacturing processes according to the ninth embodiment can be the same as those according to the fifth embodiment.

In the embodiments explained so far, the logic circuit element is formed on the bulk substrate as explained in the first embodiment. Furthermore, the surface of the bulk substrate on which the logic circuit element is formed can be set equal to the height or level of the surface of the SOI structure in which the memory cells are formed (the surface of the epitaxial layer 50 or the second epitaxial layer 52). Therefore, no difference in height or level is generated between the logic region and the memory region. As a result, the focus offset in the lithography process and the planarization defect at the CMP process can be avoided.

1. A method of manufacturing a semiconductor device comprising:
preparing a support substrate including a surface region consisting of a semiconductor single crystal;
forming a porous semiconductor layer by transforming the surface region of the support substrate into a porous layer;
epitaxially growing a single-crystal semiconductor layer on the porous semiconductor layer;
forming an opening reaching the porous semiconductor layer by removing a part of the single-crystal semiconductor layer;
forming a cavity between the single-crystal semiconductor layer and the support substrate by removing the porous semiconductor layer through the opening; and
filling the cavity with an insulating film or a conductive film.

2. The method of manufacturing the semiconductor device according to claim 1, wherein
the forming the porous semiconductor layer includes:
transforming the surface region of the support substrate into the porous layer in a first pattern, as a first porous layer transformation; and
transforming the surface region of the support substrate into the porous layer in a second pattern, as a second porous transformation, and
a portion of the porous semiconductor layer in which the first pattern overlaps with the second pattern is thicker than a portion of the porous semiconductor layer in which the first pattern does not overlap with the second pattern.

3. The method of manufacturing the semiconductor device according to claim 2, wherein
the first porous layer transformation includes transforming the surface region of the support substrate in a source region and a drain region of a floating-body cell into the porous layer, the floating-body cell storing data according to number of majority carriers accumulated in a body in an electrically floating state, and
the second porous layer transformation includes transforming the support substrate in the source region, the drain region, and a body region of the floating-body cell into the porous layer.

4. The method of manufacturing the semiconductor device according to claim 3, further comprising:
forming the porous semiconductor layer after the support substrate in a region for forming a peripheral logic circuit controlling the floating-body cell is covered with a protection film;
removing the protection film; and
epitaxially growing a single-crystal semiconductor layer on the porous semiconductor layer and the support substrate.

5. The method of manufacturing the semiconductor device according to claim 1, wherein
a trench is formed in an isolation region at the same time as the formation of the opening.

6. The method of manufacturing the semiconductor device according to claim 2, wherein
in the first porous layer transformation and the second porous layer transformation, a part of an isolation region is not transformed into a porous layer,
a support pillar consisting of a semiconductor is provided between the single-crystal semiconductor layer and the support substrate during formation of the cavity.

7. The method of manufacturing the semiconductor device according to claim 1, wherein
the porous semiconductor layer is formed by using a anodization.

8. The method of manufacturing the semiconductor device according to claim 1, wherein
after forming the cavity, an inner wall of the cavity is oxidized, thereafter, the cavity is filled with the conductive film.

9. A method of manufacturing a semiconductor device comprising:
preparing a support substrate;
forming an insulation layer on a source formation region of the support substrate;
epitaxially growing a first single-crystal semiconductor layer on the support substrate by using the insulation layer as a mask;
forming a porous semiconductor layer by transforming the first single-crystal semiconductor layer into a porous layer;
epitaxially growing a second single-crystal semiconductor layer on the porous semiconductor layer and on the insulation layer;
forming an opening reaching the porous semiconductor layer by removing a part of the second single-crystal semiconductor layer;
forming a cavity between the second single-crystal semiconductor layer and the support substrate by removing the porous semiconductor layer through the opening; and
filling the cavity with an insulating film.

10. The method of manufacturing the semiconductor device according to claim 9, wherein
the forming the porous semiconductor layer includes:
transforming the first single-crystal semiconductor layer into the porous layer in a first pattern, as a first porous layer transformation; and
transforming the first single-crystal semiconductor layer or the surface region of the support substrate into the porous layer in a second pattern, as a second porous transformation, and
a portion of the porous semiconductor layer in which the first pattern overlaps with the second pattern is thicker than a portion of the porous semiconductor layer in which the first pattern does not overlap with the second pattern,
the first pattern overlaps with the second pattern in a periphery region of the insulation layer, so that a protrusion made of a semiconductor material is provided under the insulation layer.

11. The method of manufacturing the semiconductor device according to claim 10, wherein
the first porous layer transformation includes transforming the surface region of the support substrate in a source region and a drain region of a floating-body cell into the porous layer, the floating-body cell storing data according to number of majority carriers accumulated in a body in an electrically floating state, and
the second porous layer transformation includes transforming the support substrate in the source region, the drain region, and a body region of the floating-body cell into the porous layer.

12. The method of manufacturing the semiconductor device according to claim 11, further comprising:
forming the porous semiconductor layer after the support substrate in a region for forming a peripheral logic circuit controlling the floating-body cell is covered with a protection film;
removing the protection film; and
epitaxially growing a single-crystal semiconductor layer on the porous semiconductor layer and the support substrate.

13. The method of manufacturing the semiconductor device according to claim 9, wherein
a trench is formed in an isolation region at the same time as the formation of the opening.

14. The method of manufacturing the semiconductor device according to claim 9, wherein
the porous semiconductor layer is formed by using a anodization.

15. A semiconductor device comprising:
a support substrate;
an insulating film provided on the support substrate;
a semiconductor layer provided on the insulating film;
a source layer and a drain layer formed in the semiconductor layer;
a body region provided in the semiconductor layer between the source layer and the drain layer, the body region being in an electrically floating state and accumulating or discharging charges for storing data; and
a protrusion formed on a surface of the support substrate and consisting of a semiconductor material so that the insulating film below the body region is thinner than the insulating film below the drain layer.

16. The semiconductor device according to claim 15, further comprising:
a silicon pillar provided between the support substrate and the source layer and having an opposite conductivity-type of the support substrate.

17. The semiconductor device according to claim 15, wherein
the protrusion is formed on the surface of the support substrate so that the insulating film below the source layer is thinner than the insulating film below the drain layer.

18. The semiconductor device according to claim 15, further comprising:
a plate electrode buried in the in the insulating film.

19. The semiconductor device according to claim 18, further comprising:
a silicon pillar provided between the support substrate and the source layer.
